(19) United States
(12) Patent Application Publication
(10) Pub. No.: US 2025/0093414 A1
(43) Pub. Date: Mar. 20, 2025

(54) APPARATUS FOR TESTING A DEVICE UNDER TEST SEPARATING ERRORS WITHIN A RECEIVED PATTERN ASSOCIATED WITH DIFFERENT FUNCTIONAL BLOCKS OF A DEVICE UNDER TEST OR ASSOCIATED WITH DIFFERENT BLOCKS OF ONE OR MORE BITS, METHOD AND COMPUTER PROGRAM

(71) Applicant: Advantest Corporation, Tokyo (JP)

(72) Inventors: Michael BRAUN, Böblingen (DE); Klaus WELCH, Böblingen (DE); Frank HENSEL, Stuttgart (DE); Nico MÜLLER, Renningen (DE); Arndt GERLACH, Ellwangen (DE); Ulrich KNOCH, Herrenberg (DE)

(21) Appl. No.: 18/971,433

(22) Filed: Dec. 6, 2024

Related U.S. Application Data
(63) Continuation of application No. PCT/EP2023/065148, filed on Jun. 6, 2023.

(30) Foreign Application Priority Data
Jun. 7, 2022 (EP) 2177700.6

(51) Int. Cl. G01R 31/3177

(52) U.S. Cl. CPC G01R 31/3177

(57) ABSTRACT

A test apparatus for testing a device under test, is configured to receive a pattern from the device under test, which comprises information from a plurality of functional blocks of the device under test. The test apparatus is configured to separate errors within the received pattern associated with different functional blocks of the device under test during an execution of a test program, or the test apparatus is configured to separate errors within the received pattern associated with different blocks of one or more bits during an execution of a test program. A method and a computer program are also described.

### CROSS-REFERENCE TO RELATED APPLICATIONS

This application is a continuation of copending International Application No. PCT/EP2023/065148, filed Jun. 6, 2023, which is incorporated herein by reference in its entirety, and additionally claims priority from European Application No. EP 22177700.6, filed Jun. 7, 2022, which is also incorporated herein by reference in their entirety.

Embodiments according to the invention are related to a test apparatus for testing a device under test.

Further embodiments according to the invention are related to a method for testing a device under test.

Further embodiments are related to a result per core processor.

### BACKGROUND OF THE INVENTION

Testing is an important step in the production of electronic circuitry, like, for example, integrated circuits. However, the increasing complexity of electronic circuits, e.g., integrated circuits, constitutes a significant challenge.

Accordingly, to increase the optimum usage of the available bandwidth for SCAN and functional testing, the players in EDA software and design for test started to work on methods to interleave the test patterns for different cores when sending them through the test interface into the device under test (DUT), instead of sending the pure (e.g. single core) pattern (individual cores) to the target IP cores one by one.

A “core” denotes here (in the context of the present application) a basic unit of the logical design, which shall be analysed in the testing separately (e.g., a unit of testing, the granularity of test results). For example, a core may be considered as a functional block of the device under test.

In view of this situation, there is a need for a concept which allows for a good compromise between complexity, test coverage and test time in a situation in which test patterns for different cores are interleaved.

### SUMMARY

According to an embodiment, a test apparatus for testing a device under test may have: a signal receiver configured to receive a pattern from the device under test, which includes information from a plurality of functional blocks of the device under test; and an error separator configured to separate errors within the received pattern associated with different functional blocks of the plurality of functional blocks of the device under test during an execution of a test program.

According to another embodiment, a test apparatus for testing a device under test may have: a signal receiver, and an error separator; wherein the signal receiver is configured to receive a pattern from the device under test, which includes a sequence of bits; wherein the error separator is configured to separate errors within the received pattern associated with different blocks of one or more bits during an execution of a test program.

Another embodiment relates to a method for testing a device under test, wherein the method includes receiving a pattern from the device under test, which includes information from a plurality of functional blocks of the device under test; wherein the method includes separating errors within the received pattern associated with different functional blocks of the device under test during an execution of a test program.

An embodiment according to the invention creates a test apparatus (e.g. a test processor, or a channel module of an automated test equipment, or an automated test equipment) for testing a device under test. The test apparatus is configured to receive a pattern (e.g. a result pattern; e.g. a response pattern) from the device under test, which comprises (e.g. in a combined form; e.g. in an interleaved form) information (e.g. test results; e.g. test response information; e.g. a sequence of bits) from (e.g. associated with) a plurality of functional blocks (e.g. “cores”; e.g. result blocks; e.g. functional blocks providing substantially independent test results or test responses) of the device under test. The test apparatus is configured to separate (e.g. treat separately, or record separately) errors within the received pattern associated with different functional blocks of the device under test (e.g. to separate errors of different cores) during an execution of a test program (e.g. in order to obtain test results per functional block of the device under test, e.g. per core of the device under test, during the execution of the test program).

It has been recognized that the scenario in which test results of multiple functional blocks of a device under test are combined in a common result pattern, e.g., are output in a time-multiplexed manner via a single pin of the device under test, a separation of errors within the received pattern associated with different functional blocks of the device under test during the execution of the test program allows to test the device under test in an efficient manner while avoiding to store the full received pattern, which is typically provided at a very high data rate.

For example, the separation of errors within the received pattern associated with different functional blocks of the device under test allows to get an overview which of the functional blocks of the device under test comprise an error very rapidly, e.g., without storing or buffering the received test pattern. In some cases, the concept even allows to get an overview which functional blocks of a device under test fail “heavily” (with a large number of errors associated with the heavily failing functional blocks within the received pattern) already during the execution of the test program or very shortly after the execution of the test program. For example, an a priori knowledge about positions (e.g., bit positions) within the received pattern which are associated with different functional blocks (or which are allocated to test result bits of different functional blocks) may allow for a very fast separation of errors (within the received pattern) associated with different functional blocks even during the execution of the test program.

Accordingly, it is possible to have separate information about malfunctions of different functional blocks of the device under test during the execution of the test program or shortly after the completion of the test program, which, in turn, allows to make decisions about a (further) test flow on the basis of the information about malfunctions of the different function blocks (which are indicated by errors within the received pattern at bit positions associated with the functional blocks comprising a malfunction).

To conclude, the separation of errors within the received pattern associated with different functional blocks of the device under test during the execution of the test program (which results in an information indicating malfunctions of the different functional blocks, e.g., separately for individual functional blocks, has been found to reduce the complexity of the test since it may not be necessary to store the full received pattern for a subsequent analysis when separating the errors (within the received pattern) associated with different functional blocks of the device under test “during run time” (during the execution of the test program).

Accordingly, an aggregated information may be obtained, which indicates, separately for different functional blocks of the device under test or even separately for each functional block of the device under test, whether the functional blocks of the device under test have generated errors in the received pattern. Accordingly, the test apparatus described above allows to efficiently identify one or more failing functional blocks of the device under test during the execution of a test program, even if test results of a plurality of functional blocks are combined in a received pattern (e.g. in a combined bit stream), wherein, for example, different positions within the received pattern may be associated with test results from different ones of the functional blocks of the device under test, and wherein, for example, the test apparatus may separate the test results (e.g. results of a comparison with an expected bit value) originating from different functional blocks of the device under test (or caused by different functional blocks of the device under test) based on knowledge about an association of functional blocks of the device under test to bit positions within the received pattern.

The (separate) detection of the failures of the different functional blocks of the device under test may be achieved in a very efficient manner since the separation of the errors within the received pattern associated with different functional blocks during the execution of the test program may eliminate the need to upload the received pattern to a separate processing unit for a post-processing. In particular, it may be unnecessary to save the received pattern for a later detection of errors within the received pattern by separating the errors within the received pattern during the execution of the test program (rather than as a post-processing step). Accordingly, a very good functionality can be achieved with a low complexity which helps to increase the test efficiency and also the speed of the test.

Thus, the test apparatus brings along a very good trade-off between complexity, a provided functionality and a speed of test.

In an embodiment, the test apparatus is configured to separate the errors within the received pattern associated with different functional blocks of the device under test on-the-fly (e.g. without buffering or logging a full received pattern before starting with a separation of errors associated with different functional blocks of the device under test; e.g. before a contiguous test pattern stream is completely received by the test apparatus; e.g. without recording the received stream).

By separating the errors within the received pattern associated with different functional blocks of the device under test on the fly, a buffering or logging of a full received pattern, which would be very resource-consuming, can be avoided. Thus, an on-the-fly association of bit positions within the received pattern to different functional blocks of the device under test may be used to distinguish and/or separate error information (e.g., indicating an error in the received pattern) associated with different functional blocks of the device under test. For example, the error information associated with different functional blocks of the device under test may be distributed to different error registers or error counters (associated with different functional blocks of the device under test). Thus, by using an “on-the-fly” separation of errors within the received pattern (or, equivalently, an on-the-fly routing of error information indicating errors within the received pattern) helps to reduce or minimize a buffering effort for buffering the received pattern and further avoids delays which would be caused by a post-processing after the execution of a test program.

In an embodiment, the test apparatus is configured to separate the errors within the received pattern associated with different functional blocks of the device under test in real time (e.g. at a rate which is identical to a data rate at which the received pattern is received from the device under test), and/or or in temporal synchronism with a data rate at which the received pattern is received from the device under test).

By separating errors within the received pattern associated with different functional blocks of the device under test in real time, it is not necessary to buffer a significant portion of the received pattern or even the full received pattern. Rather, the separation of the errors (or, equivalently, the separation of an error formation indicating errors within the received pattern) in real time allows that error information indicating errors within the received pattern is available already during the reception of a contiguous pattern. In other words, error information describing an error that occurs in a first portion of the received pattern may be available before a subsequent portion of the same contiguous pattern is received by the test apparatus. Also, in some cases, it may be sufficient to buffer a very short portion of the received pattern that is needed for the actual error detection, but after the errors are separated (in real time) the received pattern can be discarded. In some implementation, a buffering of the received pattern may even be fully avoided. Thus, it has been recognized that the separation of errors (or, more precisely, the separation of an error information describing errors within the received pattern) helps to make the error handling more efficient and to have error information available very quickly.

However, in some embodiments, tester hardware does detect the errors in the received patterns (“exactly”) on the fly, real time. This means that the “Edge comparator”, as it is often called, analyzes the logic level at the programmed time and compares against the expected state. The errors identified in this process are combined, for example, first within a so-called test processor period (for example, max. 8 comparators) and then, for example, in a so-called comparator word (for example, 4 of the above). The further processing (analysis of the fails with respect of the core it belongs to) in this sense is not instantaneous any more, but (only) delayed by a short time, e.g. by a few nanoseconds. In the big picture of data processing (and in the sense of the present application), this processing is, however, considered as “on the fly”. Also, this processing is on close temporal synchronism with a data rate at which the received pattern is received from the device under test and in temporal synchronism with a data clock at which the received pattern is received from the device under test.

In an embodiment, the test apparatus comprises a dedicated hardware (e.g. a multiplexer) configured to separate errors within the received pattern associated with different functional blocks of the device under test.

By using a dedicated hardware to separate errors within the received pattern, particularly fast and efficient processing can be achieved. In particular, it should be noted that the received pattern typically comprises a very high data rate, such that a dedicated hardware is particularly advantageous and allows for the “on-the-fly” or “real-time” processing and separation of errors associated with different functional blocks of the device under test.

In particular, the usage of a dedicated hardware may eliminate the need for the storage of the received pattern, which, in turn, significantly reduces a resource demand of the concept. Furthermore, it has been recognized that a dedicated hardware is typically much more energy efficient when compared to a microprocessor-based (e.g. software-controlled) separation of errors within the received pattern. Accordingly, by using a dedicated hardware, the separation of errors within the received pattern associated with different functional blocks of the device under test may be performed even before a logging of erroneous bits is made, and the hardware based separation of errors may also be used to control the logging of erroneous bits of the received pattern.

To conclude, it has been recognized that usage of dedicated hardware for the separation of errors within the received pattern associated with different functional blocks of the device under test may increase the power efficiency and may also bring along a very fast provision of error information indicating (or describing) errors associated with different functional blocks of the device under test. Accordingly, the error information obtained by the separation of errors associated with different functional blocks of the device under test can be used in further processing steps, for example, in the logging of erroneous bits of the received pattern.

In an embodiment, the test apparatus comprises a dedicated hardware (e.g. a multiplexer; e.g. a core mapper) configured to selectively forward an error signal indicating a deviation of a bit value of a bit of the received pattern associated with a certain functional block of the device under test (e.g. at a bit position associated with the certain functional block of the device under test) from an expected bit value defined by the expected pattern to a result unit (e.g. an error flag register, or an error counter) associated with the certain functional block of the device under test (or equivalently, associated with a bit position within the received pattern) (e.g. out of a plurality of result units associated with different functional blocks of the device under test, or, equivalently, of result units associated with different bit positions of the received pattern). For example, the dedicated hardware may determine to which result unit an error signal should be forwarded in dependence on a currently considered bit position, and using an allocation rule defining an association of bit positions with functional blocks of the device under test, or, equivalently, defining an association of bit positions.

By selectively forwarding the error signal indicating a deviation of a bit value of a bit of a received pattern associated with a certain functional block of the device under test from an expected bit value defined by an expected pattern to a result unit associated with a certain functional block of the device under test, the separation of the errors within the received pattern associated with different functional blocks of the device under test can be performed in a very fast and efficient manner. For example, the comparison between the expected bits merely defined by the expected pattern and the bit value of the bit of the received pattern can be performed in a particularly efficient manner in hardware, wherein it should be noted that current test apparatuses comprise powerful and efficient mechanisms for providing an electrical signal representing the expected pattern.

Thus, for example, an output signal of a very fast comparator, which compares an electrical signal representation of the received pattern with an electrical signal representation of the expected pattern, can provide a result signal (e.g., in the form of an electrical signal), and such a (comparison) result signal, which may also be considered as the error signal, can, for example, be distributed efficiently using a multiplexer (to thereby selectively forward the error signal to a respective result unit).

It has also been recognized that the selective forwarding of the error signal to a respective result unit (wherein, for example, different result units may be associated with different functional blocks of the device under test) can be controlled by a hardware mechanism which tracks an association of bits (or bit positions) of the received pattern with different functional blocks of the device under test. Accordingly, the selective forwarding of the error signal (e.g., by a multiplexer) to different result units can be controlled by the functional block (of the test apparatus) tracking the association of the bit positions of the received pattern with different functional blocks of the device under test.

Consequently, the separation of the errors associated with different functional blocks of the device under test can be achieved by the dedicated hardware in a fast, reliable and power efficient circuitry. Moreover, the different result units, which may be associated with different functional blocks of the device under test, may separately log or count errors associated with different functional blocks of the device under test, such that an information (e.g. a separate information) about an occurrence of one or more errors in different functional blocks of the device under test is available in the resource units. Accordingly, the information provided by the result units can be used for the assessment of the device under test and/or for the control of the test flow and/or for any other test purposes.

In an embodiment, the test apparatus comprises a dedicated hardware configured to selectively disable a comparison (e.g. performed by a comparator) between one or more bits of the received pattern associated with a certain functional block of the device under test (e.g. at a bit position associated with the certain functional block of the device under test) and one or more corresponding bits of the expected pattern (e.g. based on the identified logical block or functional block the error belongs to) and/or to selectively disable a forwarding of a result of a comparison (e.g. performed by a comparator) between one or more bits of the received pattern associated with a certain functional block of the device under test (e.g. at a bit position associated with the certain functional block of the device under test) and one or more corresponding bits of the expected pattern (e.g. based on the identified logical block or functional block the error belongs to) and/or to selectively disable a processing of a result of a comparison (e.g. performed by a comparator) between one or more bits of the received pattern associated with a certain functional block of the device under test (e.g. at a bit position associated with the certain functional block of the device under test) and one or more corresponding bits of the expected pattern (e.g. based on the identified logical block or functional block the error belongs to).

Using such a concept, it is possible to selectively mask a handling of errors associated with one or more specified functional blocks of the device under test. This is particularly helpful if it has been recognized that a certain functional block of a device under test generates a high number of errors which would jam further processing units. For example, a logging or a more detailed analysis of such errors can be disabled using the described mechanism, which may, for example, help to maintain (save) sufficient resources for a handling of errors caused by functional blocks of the device under test which only exhibit a small (and well-manageable) number of errors. Thus, for example, when it has been found in a previous run of the test program (or of a portion of the test program) that a functional block of the device under test causes an excessive number of errors in the received pattern, the test apparatus can be relieved from handling of this high number of errors and focus on the testing of other functional blocks of the device under test. Accordingly, a test efficiency can be significantly improved in some cases, which may also result in a reduction of test time.

Worded yet differently, a waste of testing resources on a functional block of the device under test generating an excessive number of errors in the received pattern can be avoided.

In an embodiment, the test apparatus comprises a dedicated hardware configured to identify different blocks of one or more bits of the received pattern associated with different functional blocks of the device under test, in order to separate errors within the received pattern associated with different functional blocks of the device under test.

By using a dedicated hardware that identifies different blocks of one or more bits of the received pattern associated with different functional blocks of the device under test, the separation of errors within the received pattern associated with different functional blocks of the device under test may be facilitated. For example, a periodicity of an association of different blocks of one or more bits of the received pattern to functional blocks of the device under test may be exploited to efficiently identified different blocks of one or more bits of the received pattern associated with different functional blocks of the device under test. Moreover, the dedicated hardware may exploit the fact that there may be a well-defined association rule between blocks of one or more bits of the received pattern and functional blocks of the device under test. For example, this association pool may be defined by a repetitive sequence, wherein length of blocks of one or more bits associated with different functional blocks of the device under test may be known (e.g., may be predetermined, or may be defined in a lookup table, or the like). However, by using a dedicated hardware to identify different blocks of one or more bits of the received pattern associated with different functional blocks of the device under test, a fast and power-efficient solution is provided which allows for the separation of errors in accordance with the identification of blocks of one or more bits of the received pattern associated with the different functional blocks of the device under test.

It has been found that the usage of such a table provides for an efficient and well-configurable identification of different blocks of one or more bits of the received pattern associated with different functional blocks of the device under test. In particular, a table defining names of blocks of one or more bits of the received pattern associated with different functional blocks of the device under test has been found to be an efficient and well-configurable description of the typically repetitive occurrence of bits associated with different functional blocks of the device under test within the received pattern. Also, it has been recognized that such a table can be efficiently evaluated using a dedicated hardware, which results in an efficient implementation.

In an embodiment, the test apparatus comprises a reference pattern generator configured to generate a time signal representing the expected pattern, and wherein the test apparatus comprises a comparator circuit configured to compare a time signal representing the received pattern with the time signal representing the expected pattern, wherein the comparator is configured to provide an error signaling (e.g. by activating an error signal) in response to a deviation between a bit of the expected pattern and a bit of the received pattern (wherein the test apparatus is configured to selectively activate and/or deactivate the comparison performed by the comparator, and/or wherein the test apparatus is configured to selectively forward this error signaling to one out of a plurality of result units in dependence on a current bit position, to thereby separate errors within the received pattern associated with different functional blocks of the device under test).

It has been recognized that the usage of a reference pattern generator and of a comparator circuit allows for an efficient implementation of the concept, wherein the reference pattern generator can typically be reused for other functionalities of the test apparatus. Furthermore, the comparator may also be used for the testing of conventional devices under test which do not multiplex test results of multiple functional blocks in a single signal. Accordingly, it has been recognized that the implementation is particularly efficient and well suited for the integration into a test apparatus.

In an embodiment, the test apparatus is configured to individually track test results (e.g. error flags, error counts) of different functional blocks of the device under test (wherein the test results may, for example, be based on the errors within the received pattern).

Accordingly, the test apparatus may provide individual information indicating whether a functional block has generated an error and/or indicating how many errors a functional block has generated. Thus, an overview over an error status (whether an error has occurred, or how many errors have occurred) of different functional blocks is available already during the execution of a test program and may, for example, be used to make test flow decisions in dependence thereon. Furthermore, the fundamental test results, e.g., whether a functional block of the device under test has generated an error, is available without further post-processing (right) after the completion of the test program, which makes the testing highly time-efficient.

In an embodiment, the test apparatus is configured to individually track test results (e.g. error flags, error counts) of different functional blocks of the device under test, which are derived on the basis of the (e.g. common) received pattern, per test pattern (wherein the apparatus may, for example, read out one or more result units between a provision of subsequent test patterns to the device under test, and/or wherein the test apparatus may, for example, reset one or more result units between a provision of subsequent test patterns to the device under test) or per test execution (wherein, for example, a test execution may comprise a provision of a plurality of test patterns (to the device under test)).

Accordingly, an overview over the integrity of different functional blocks of the device under test may efficiently be obtained on a per-test-pattern basis (if desired). Alternatively, the overview over the integrity of the different functional blocks may be obtained on a per-test-execution basis if this is sufficient. In other words, result units individually logging (or counting) the test results of different functional blocks of the device under test may, for example, be read out on a per-test-pattern basis. This provides a test flow control or a user of the test apparatus with information which test pattern(s) have caused the different functional blocks of the device under test to generate one or more errors. Consequently, the test flow control or the user of the test apparatus is provided with highly informative test results, wherein the separation of the errors associated with different functional blocks of the device under test during the execution of the test program allows for a very fast provision of these meaningful test results.

Result units individually tracking test results of different functional blocks may, for example, be provided with “hold” functionalities (to temporally save a test result) and/or with reset functionalities (to perform a reset at times defined, for example, by the test program). Moreover, it should be noted that the test program may also control a readout of the result units (individually tracking test results of different functional blocks of the device under test) and/or a reset of the result units.

Thus, a meaningful information is provided with good efficiency and no latency (or very small latency).

In an embodiment, the apparatus comprises a plurality of result units associated with different functional blocks of the device under test. The test apparatus is configured to selectively reset one or more of the result units (e.g. between a provision of the subsequent test patters to the device under test), and/or the test apparatus is configured to selectively freeze one or more of the result units (e.g. between a provision of the subsequent test patters to the device under test).

By having the possibility to selectively reset one or more of the result units and/or to selectively freeze one or more result units, it is possible (e.g. for the test program or for the test flow control) to determine for which time portions results describing errors provided by the different functional blocks of the device under test shall be determined. For example, by resetting a result unit, the result unit can be prepared for a logging of a result for a desired portion of the test program. Moreover, by freezing a result unit, it can be achieved that a result unit is left unaffected by errors that occur during a certain portion of a test program. Moreover, by resetting and/or freezing the result units, e.g., under the control of a test program, it can be ensured that reliable and meaningful results can be read out from the result units.

In an embodiment, the test apparatus is configured to compare a received pattern with an expected pattern. Moreover, the apparatus is configured to separately register comparison failures associated with different blocks of one or more bits of the received pattern, and/or to separately register comparison failures associated with different functional blocks of the device under test (wherein the different blocks of one or more bits of the received pattern may be associated with different functional blocks of the device under test).

By comparing a received pattern with an expected pattern and by separately registering comparison failures associated with different blocks of one or more bits of the received pattern, and/or by separately register comparison failures associated with different functional blocks of the device under test, the test apparatus can efficiently determine (e.g., record) errors occurring in different functional blocks of the device under test, since different blocks of one or more bits of the received pattern are typically associated with these different functional blocks of the device under test. Accordingly, a meaningful test result information can be provided which is indicative of the integrity of different functional blocks of the device under test.

In an embodiment, the test apparatus is configured to separately register comparison failures associated with different functional blocks of the device under test using a mapping scheme defining an association of bits of the received pattern to different result units registering the comparison failures (e.g. error flag registers or error counters), and/or using a mapping scheme defining an association of bits of the received pattern to different functional blocks of the device under test.

For example, the mapping scheme defining an association of bits of the received pattern with different result units registering the comparison failures may be equivalent to the mapping scheme defining an association of bits of the received pattern to different functional blocks of the device under test. For example, the different result units may be associated with the different functional blocks of the device under test.

Such a concept which makes use of a mapping scheme may provide a test result that characterizes the integrity of the device under test in a particular meaningful manner, namely separately per functional block of the device under test. The mapping scheme may reflect the inclusion of result bits associated with different functional blocks of the device under test into the pattern that is received by the test apparatus. Accordingly, the test result may help the test flow control or the user of the automated test equipment to judge the device under test, wherein the test result is typically provided with very low latency since the separate registration of comparison failures may typically take place during the execution of the test program, wherein, for example, the mapping scheme may be implemented in such a form that it can be evaluated “on the fly” or in real time.

In an embodiment, the test apparatus comprises a plurality of individual result units configured to (e.g. individually) track test results (e.g. fails) associated with different functional blocks of the device under test (e.g. to individually track deviations of different blocks of bits of the received pattern from corresponding bits of the expected pattern; e.g. to individually track deviations between bits (e.g. blocks of bits) of the received pattern associated with different functional blocks of the device under test form corresponding bits of the expected pattern).

By using individual result units, which separately track test results associated with different functional blocks of the device under test, the integrity of different functional blocks of the device under test can be determined individually. Accordingly, it is possible to distinguish functional blocks of the device under test which show one or more errors, from the non-defective functional blocks in a very fast and efficient manner. For example, if the individual result units are implemented using separate hardware (e.g., using separate error registers which are set by the first occurrence of an error in the received pattern associated with a given functional block of a device under test, and which are, for example, reset by a dedicated reset signal, or using separate counters, each of which counts errors within the received pattern associated with one or more functional blocks of the device under test, meaningful test results can be achieved in a fast and efficient manner, e.g., without needing any post-processing of the received patterns using a microprocessor. Since the separate individual result units may be “triggered” (e.g., to register the presence of an error associated with a certain functional block of the device under test) in real time or in synchronism with a data clock of the incoming received pattern, the buffering of a large portion of the received pattern may be unnecessary. It has been found that individual result units implemented in hardware are particularly suitable for such an application.

In an embodiment, the test apparatus comprises a plurality of individual error flag registers associated with different functional blocks of the device under test.

It has been found that individual error flag registers can be implemented with a very low effort. For example, the individual error flag registers may be “sticky” registers which are set at the first occurrence of an error associated with a respective functional block of a device under test. Thus, for example, each error flag register may be associated with one or more functional blocks of the device under test, and an error in the received pattern originating from said one or more respective functional blocks of the device under test may result in a setting of the error flag register. Thus, a state of the error flag register may effectively indicate whether one or more functional blocks associated with the respective error flag register exhibit an error (such that one or more bits in the received pattern associated with this functional block(s) deviate from the expected bit values). Accordingly, the error flag registers provide a very compact “go/no go” or “pass/fail” information for different functional blocks of the device under test, wherein such a “go/no go” information may be very helpful for a classification of the device under test and/or for decisions about the test flow.

In an embodiment, the test apparatus comprises a plurality of individual error flag registers configured to be set in response to comparison errors (e.g. deviations) between bits of the received pattern and corresponding bits of the expected pattern occurring in different blocks of one or more bits of the received pattern (wherein, for example, the different individual error flags are (individually) associated with comparison errors in different blocks of one or more bits of the received pattern, and wherein, for example, the different blocks of one or more bits of the received pattern are associated with different functional blocks of the device under test).

It has been found that such an arrangement allows a meaningful test result, wherein a decision, which of the individual error flag registers should be set, may be made in accordance with the separation of the errors associated with different functional blocks of the device under test. For example, the above mentioned multiplexer, which is controlled in accordance with a mapping rule or mapping scheme, can be used to decide which individual error flag register, out of a plurality of error flag registers, is set in response to an error signal. For example, the error signal may be selectively forwarded in accordance with a distinction of different blocks of one or more bits within the received pattern. To conclude, the individual error flag registers may constitute a very efficient approach to obtain a test result information.

In an embodiment, the test apparatus comprises a plurality of individual error counters associated with different functional blocks of the device under test.

The presence of individual error counters, which may, for example, individually count errors within the received pattern associated with different functional blocks of a device under test is very helpful to obtain a meaningful test information about the different functional blocks. For example, the error counters may allow to recognize how many errors within the received pattern the different functional blocks generate. Accordingly, functional blocks which do not generate any error, functional blocks which generate only a small number of errors and functional blocks which generate a large number of errors can be distinguished.

Accordingly, count values of the individual error counters may be evaluated to classify the different functional blocks of the device under test, which may, in turn, be used to obtain an overall classification of the device under test and/or to control a test flow. Accordingly, it is apparent that usage of individual error counters is a very powerful tool which gives meaningful insights of the functionality of the device under test.

In an embodiment, the test apparatus comprises a plurality of individual error counters configured to be incremented in response to comparison errors (e.g. deviations) between bits of the received pattern and corresponding bits of the expected pattern occurring in different blocks of one or more bits of the received pattern (wherein, for example, the different individual error counters are (individually) associated with comparison errors in different blocks of one or more bits of the received pattern; wherein, for example, the different individual error counters are configured to count errors in different blocks of one or more bits of the received pattern; wherein, for example, the different blocks of one or more bits of the received pattern are associated with different functional blocks of the device under test).

It has been found that such individual error counters allow to obtain a meaningful test information regarding different functional blocks of the device under test in an efficient and fast manner.

In an embodiment, the test apparatus is configured to selectively set an error flag (e.g. a single error flag; e.g. a sticky error flag which remains active until a reset is explicitly effected), out of a plurality of individual error flags (e.g. associated with different functional blocks of the device under test), in response to a detection of a deviation between a bit of the received pattern and a bit of the expected pattern (e.g. reference pattern) and in dependence on an association rule (which, for example, defines an association between bits of the received pattern and functional block of the device under test, and/or an association between bits of the received pattern and error flags; which may, for example route an error signal indicating a comparison error to a set input of a respective error flag register). The association rule may, for example, be flexible, e.g., in some form programmable.

Using such a concept in which an association rule determines which error flag, out of a plurality of individual error flags, should be set in response to a detection of a deviation between a bit of the received pattern and a bit of the expected pattern constitutes an efficient mechanism for dealing with received patterns in which different bits or groups of bits are associated with different functional blocks of the device under test. Accordingly, different individual error flags can signal errors caused by different functional blocks of the device under test. However, by using a flexible association rule, which may, for example, be programmable, the test apparatus can be adapted to different devices under test, wherein the association between bit positions in the received pattern and functional blocks of the device under test may vary between the different devices under test.

In an embodiment, the test apparatus is configured to set an individual error flag associated with a given functional block of the device under test in response to a detection that a bit of the received pattern associated with the given functional block of the device under test deviates from an expected pattern, in order to separately register comparison failures associated with different functional blocks of the device under test.

Accordingly, by setting an individual error flag in response to a detection that a bit of the received pattern associated with a given functional block of the device under test deviates from an expected pattern, a meaningful test result information characterizing different functional blocks of the device under test can be obtained with little effort.

In an embodiment, the test apparatus is configured to selectively increment an error counter (e.g. an individual error counter), out of a plurality of individual error counters (associated with different functional blocks of the device under test), in response to a detection of a deviation between a bit of the received pattern and a bit of the expected pattern (reference pattern) and in dependence on an association rule (which defines an association between bits of the received pattern (e.g. blocks of bits of the received pattern) and functional block of the device under test, and/or an association between bits of the received pattern and error counters; which may, for example route an error signal indicating a comparison error to an increment input of clock input of a respective error counter).

By using such a configuration, details regarding the integrity of different functional blocks of the device under test can be obtained with moderate effort. For example, the association rule determines which of the error counters is incremented in response to the detection of a deviation between a bit of the received pattern and a bit of the expected pattern. For this purpose, the association rule may be based on a-priori knowledge which bit positions within the received patterns are associated with which functional blocks of the device under test. Consequently, a very meaningful error information characterizing the device under test can be obtained in a very quick manner, without invoking a large processing time.

In an embodiment, the test apparatus is configured to increment an individual error counter associated with a given functional block of the device under test in response to a detection that a bit of the received pattern associated with the given functional block of the device under test deviates from an expected pattern, in order to separately count comparison failures associated with different functional blocks of the device under test.

Accordingly, a reliable characterization of different functional blocks of the device under test can be achieved, e.g., using a low complexity hardware. For example, a microprocessor based evaluation of the received pattern is not required to obtain meaningful error information regarding the different functional blocks of the device under test.

In an embodiment, the apparatus is configured to record individual failure information (which can, for example, be upload to a work station for a detailed analysis, e.g. after an execution of a test) indicating a respective failure position for a plurality of comparison failures (such that the individual failure information describes an actual bit position of a respective comparison failure within the received pattern). Moreover, the apparatus is configured to obtain an overview failure information (e.g. an overview failure map; e.g. an information describing a state of a plurality of error flag registers; e.g. an information describing a state of a plurality of error counters) separately describing errors (e.g. comparison errors) associated with different functional blocks of the device under test in summary form (e.g. in the form of a single binary value per functional block of the device under test, indicating whether at least one bit of the received pattern associated with the respective functional block of the device under test has deviated from a corresponding bit of the reference pattern, or in the form of a single counter value per functional block, indicating a number of bits of the received pattern associated with the respective functional block of the device under test that have deviated from corresponding bits of the reference pattern).

It has been found that the determination of both individual failure information, which allows to precisely determine which bit in the received pattern is erroneous, and of an overview failure information, which only signals which of the different functional blocks of the device under test produce an error within the received pattern (and which optionally provides an information how many errors within the received pattern a functional block has generated) allows for an efficient testing of the device under test. For example, the overview failure information, which typically does not comprise a precise information about a position of an erroneous bit within the received pattern, allows for a quick decision whether a functional block of the device under test does not generate any errors or whether a functional block of the device under test produces one or more errors. In some cases, the overview failure information may also allow to distinguish between functional blocks generating a very small number of errors within the received pattern and functional blocks generating a large number of errors within the received pattern, e.g., if there is an error counter. Thus, the overview failure information may be available very quickly and may be well-suited for making test flow decisions in view of the fast availability. Furthermore, the overview failure information comprises the most relevant information, namely the question which functional blocks of the device under test generates errors within the received pattern, in a very compact form.

On the other hand, the recorded individual failure information allows for a more detailed analysis by the user of the test equipment. Since the recorded individual failure information may typically indicate which bit within the received pattern has been erroneous and may therefore allow for a very detailed identification of the origin of the error (e.g., down to a single gate level or even down to a single transistor level). However, it should be noted that, under given resource constraints, an amount of individual failure information that can be recorded is typically limited. Thus, there may be situations in which the limited amount of recorded individual failure information only describes errors originating from a single functional block of the device under test, while the overview failure information also allows to recognize errors originating from other functional blocks of the device under test.

Furthermore, it should be noted that the overview failure information is typically available much faster and/or allows to make some conclusions much faster than the individual failure information, since the individual failure information typically comprises a much larger amount of information, e.g., detailed error position information, and the like.

To conclude, it has been recognized that the determination of both individual failure information and the overview failure information is valueable, since the overview failure information is particularly well-suited for obtaining an overview over the integrity of the device under test and/or for the classification of the device under test and/or for making test flow decisions, while individual failure information allows for a more detailed analysis of a failure.

In an embodiment, the apparatus is configured to record failing cycles (e.g. bits of the received pattern for which the comparison with the reference pattern indicates a deviation) in an temporally identifiable (e.g. temporally documented, traceable) manner (e.g. together with a bit position information or a time stamp information) (e.g. with a limited logging capacity) in addition to a per-functional-block error flag and/or a per-functional-block error counting.

By recording failing cycles in a temporally identifiable manner in addition to a per-functional-block error flag and/or a per-function-block error counting, the test apparatus makes available both a compact overview information which is well-usable for a classification of devices under test and/or for test flow decisions and a more detailed information which is well-suited for a detailed analysis of errors. By recording failure cycles, e.g., with a time stamp or a bit position value, there is information available which is particularly useful if a number of errors is comparatively small. This record of failing cycles in a temporally identifiable manner may, for example, be stored in a test apparatus, and may, for example, be analysed in a post-processing step following the execution of a test program. Alternatively or in addition, the record of failing cycles in a temporally identifiable manner may, for example, be uploaded from the test apparatus to a work station, where it may be analysed further using a software tool. The per-functional block error flag and/or the per-functional-block error counting may, for example, be evaluated during execution of the test program and may, for example, be used directly for a classification of a device under test or for controlling an execution of a test flow. For example, the per-functional-block error flag and/or the per-functional-block error counting may be used to determine which test should be performed next in a test flow.

Thus, the concept to record both a detailed information about failure cycles and a compact “summary” information allows for a fast, efficient and thorough testing and allows for a detailed insight into the integrity of the device under test.

In an embodiment, the test apparatus is configured to continue updating the overview failure information (e.g. the per-functional-block error flag and/or the per-functional-block error counting) even if a memory for recording the individual failure information is exhausted (e.g. by a high number of comparison failures).

Accordingly, the overview failure information provides a reliable information about the functional status of different functional blocks of the device under test even if there is a large number of individual failure information which may, for example, be caused by heavily defective functional blocks. Thus, the overview failure information allows for classifying a device under test and/or for making test flow decisions very rapidly even in situations in which there is a large number of bit errors in the received pattern. Accordingly, it is, for example, possible to recognize non-defective functional blocks of the device under test even if a single defective block of the device under test generates a large number of errors in the received pattern and jams a recording of the individual failure information. Thus, a test efficiency can be significantly improved.

In an embodiment, the test apparatus is configured to selectably mask (e.g. omit) (e.g. on a per-functional-block-basis, or with a per-functional-block granularity) a recording of individual failure information (e.g. an error map recording) for bits of the received pattern which are associated with one or more functional blocks of the device under test. Alternatively or in addition, the test apparatus is configured to selectably enable (e.g. on a per-functional-block-basis, or with a per-functional-block granularity) a recording of individual failure information (e.g. an error map recording) for bits of the received pattern which are associated with one or more functional blocks of the device under test.

By selectively masking or selectively enabling a recording of individual failure information, for bits of the received pattern which are associated with one or more functional blocks of the device under test allows to concentrate the resources available for the recording of the individual failure information onto failures of one more functional blocks of special interest. Alternatively, by selectively masking or selectively enabling the recording of the individual failure information, a recording to an individual failure information can be avoided for one or more heavily failing functional blocks of the device under test, to thereby avoid a jamming of the resources for the recording of the individual failure information. Accordingly, it is possible to have a recording of individual failure information which focuses on failures caused by one or more selected functional blocks of the device under test. Consequently, a particular meaningful individual failure information can be obtained in a resource-saving manner.

In an embodiment, the test apparatus is configured to determine for which bits of the received pattern a recording of individual failure information should be omitted (masked) using a table defining lengths of blocks of one or more bits of the received pattern associated with different functional blocks of the device under test.

Accordingly, a table can be used to define a selection of bits of the received pattern for which an individual failure information should be recorded or should not be recorded. Thus, a selective masking of a part of the individual failure information can be achieved, which may, for example, help to avoid a jamming of the individual failure recording. In particular, it has been recognized that a usage of a table defining length of blocks of one or more bits of the received pattern associated with different functional blocks of the device under test is an efficient mechanism to distinguish between bits of the received pattern for which an individual failure information should be recorded and bits of the received pattern for which an individual failure information should not be recorded.

In an embodiment, the test apparatus comprises a dedicated hardware configured to identify (e.g. at runtime; e.g. during a reception of the received pattern from the device under test) bits of the received pattern for which a recording of individual failure information should be omitted (e.g. masked) (e.g. using a table defining lengths of blocks of one or more bits of the received pattern associated with different functional blocks of the device under test, and optionally a length of a startup block, and optionally a periodicity).

By using a dedicated hardware to identify bits of the received pattern for which the recording of individual pattern information should be omitted, a particularly efficient implementation can be achieved. In particular, by using a dedicated hardware, a just-in-time processing can be performed, which eliminates the need for extensive buffering mechanisms. For example, when using a dedicated hardware, the generation of the individual failure information can be enabled or disabled at a very early stage of the processing chain, e.g., by suppressing a comparison or by disabling (or interrupting) an error signalling of the comparison between the received pattern and the reference pattern. Accordingly, the computational complexity can be kept very small and the memory requirements can also be relaxed.

In an embodiment, the test apparatus is configured to (e.g. automatically) activate a (e.g. selective) masking of a recording of individual failure information (e.g. selectively) for bits of the received pattern which are associated with a certain functional block of the device under test (e.g. at runtime; e.g. during a reception of a received pattern from the device under test) in response to a detection that an individual error counter selectively counting comparison errors of bits associated with the certain functional block has reached a predetermined maximum value (e.g. such that a recording of individual failure information associated with the certain functional block is automatically stopped when the predetermined maximum number of failures generated by that certain functional block has been reached).

Using such a mechanism, a recording of individual failure information can be associated with a certain functional block can be stopped if it is recognized that the certain functional block generates an excessive number of errors. Thus, by counting the number of errors originating from the certain functional block of the device under test, an amount of individual failure information associated with the certain functional block of the device under test can be limited. This helps to avoid a jamming of the recording of individual failure information in the presence of one or more heavily failing functional blocks of the device under test. Instead, individual failure recording capacity is maintained for errors originating from other functional blocks of the device under test. Thus, particularly meaningful test results are obtained since the concept maintains the possibility to record individual failure information for several functional blocks of the device under test even in the presence of a heavily failing functional block (and even in view of capacity limitations for the recording of individual failure information). Thus, the concept allows to have a meaningful test result, which can be analysed by the user of the test apparatus, wherein an amount of individual failure information per functional block can be limited. However, this limitation of the amount of individual failure information per functional block is typically not a problem, since for heavily failing functional blocks it is typically not required to have a full individual failure information.

Thus, the concept allows for a very efficient test execution and provides for a meaningful test result.

In an embodiment, the test apparatus is configured to identify different blocks of one or more bits of the received pattern (e.g. as being associated with different functional blocks of the device under test) using a table defining lengths of blocks of one or more bits of the received pattern associated with different functional blocks of the device under test (and optionally a length of a startup block, and optionally a periodicity).

It has been recognized that identifying different blocks of one or more bits of the received pattern using a table defining length of blocks of one or more bits of the received pattern associated with different functional blocks of the device under test is a very efficient concept, since it is well in agreement with the typical structure of the received pattern, which comprises a sequence of blocks of bits associated with different functional blocks of the device under test, wherein said blocks of one or more bits comprise predetermined lengths that can easily be represented in a table. Moreover, a periodicity of the blocks of bits associated with different functional blocks of the device under test can also be considered in the mechanism. Consequently, an efficient implementation of the concept can be reached which reliably identifies different blocks of one or more bits of the received pattern associated with different functional blocks of the device under test and therefore allows for a separation of errors originating from these different functional blocks of the device under test.

In an embodiment, the test apparatus is configured to identify a periodic sequence of blocks of one or more bits of the received pattern associated with different functional blocks of the device under test using the table (e.g. such that there is a periodic association of blocks of bits to different functional blocks).

By exploiting the periodicity of the received pattern, the complexity of a mechanism for separating errors originating from different functional blocks of the device under test can be significantly reduced. For example, the table of the table-based mechanism may comprise an entry defining a periodicity. However, the table of the table-based mechanism may also, for example comprise a mechanism for recognising an initial portion of the received pattern to be neglected. Thus, use of the table may, for example, define lengths of portions of one more bits associated with different functional blocks of the device under test. If appropriate, the table may define a pair of values comprising a length information and an index of a functional block. In addition, the table may, for example, comprise a reference back to a proceeding table entry, to thereby represent a periodicity.

To conclude, the table-based mechanism may, for example, comprise a listing of lengths of blocks of one or more bits as well as a listing of indices of functional blocks associated with the blocks of one or more bits, and a periodicity information defining, for example, a repetition of a sequence or subsequent of blocks of bits. Accordingly, the separation of errors associated with different functional blocks of the device under test can be achieved in an efficient manner, since the evaluation of the table allows for a reliable association of bits of the received pattern with functional blocks.

In an embodiment, the test apparatus is configured to adapt a test flow in dependence on an information about an error within the received pattern associated with a given functional block of the device under test (e.g. in dependence on a value of an error flag register associated with the given functional block of the device under test and/or in dependence on a value of an error counter associated with the given functional block of the device under test).

Accordingly, the test flow can be adapted in accordance with a result information describing test results of individual functional blocks of the device under test, wherein this test information is available very quickly (and even during the execution of a test program) due to the separation of errors associated with different functional blocks of the device under test that occurs during the execution of a test program. Consequently, the rapid availability of test results associated with different functional blocks of the device under test, which is achieved by the concept disclosed herein, is exploited to improve the quality of the test. For example, if it is found that a certain functional block of the device under test generates one or more errors in the received pattern, a re-testing of this specific functional block can be triggered. On the other hand, if the test result information, which is obtained during the execution of the test program (by the separation of errors associated with different functional blocks of the device under test) indicates that a certain functional block fails heavily, the test can be adapted in such a manner that the testing of this certain heavily filling functional block is omitted in order to efficiently obtain meaningful test results for the other functional blocks. Thus, test result information associated with different functional blocks of the device under test, which are obtained by the separation of errors during the execution of the test program, can be used to impact decisions about the execution of the test flow. Consequently, a high test efficiency can be achieved by performing test programs or test functionalities which are adapted to the previously obtained test result information.

In an embodiment, the test apparatus is configured to adapt a test flow in response to a determination (e.g. a finding or a detection) that an number of errors (e.g. a number of comparison errors) in the received pattern which are associated with a given functional block of the device under test has reached or exceeded a predetermined maximum number.

Using this concept, the test flow may, for example, be adapted in such a manner that a heavily failing functional block does not degrade the reliability or the efficiency of a further testing of the device under test. For example, the further testing may be restricted to other functional blocks of the device under test, which has been found to generate no errors or only a small number of errors. For example, it may be avoided to spend test time on the testing of a functional block that has already been identified as generating a high number of errors, since it cannot be expected that this functional block is non-defective. Consequently, test resources (e.g., test time and/or individual failure recording capacity) can be focused on a testing of functional blocks of the device under test that do not generate an excessive number of errors in the received pattern. Consequently, a good test efficiency can be achieved.

In an embodiment, the test apparatus is configured to activate a masking of a recording of individual failure information, or deactivate a recording of individual failure information, for bits of the received pattern which are associated with the given functional block of the device under test and to repeat a test (e.g. a full test flow or a portion of a test flow) (e.g. with a same multi-core test pattern and a same expected pattern) in response to a determination (e.g. a finding or a detection) that an number of errors (e.g. a number of comparison errors) in the received pattern which are associated with a given functional block of the device under test has reached or exceeded the predetermined maximum number (e.g. a limit).

Using such a concept, it can be ensured that a sufficient amount of individual failure information can be recorded for a plurality of different functional blocks of the device under test even in the presence of a heavily failing functional block of the device under test. In particular, if it is found that a certain functional block of the device under test produces an excessive number of errors, individual recording of these errors can be automatically disabled, such that, in a re-execution of a test program, there is sufficient recording capacity for individually recording errors originating from other functional blocks of the device under test (other than the heavily failing functional block of the device under test).

Consequently, a meaningful test result can be obtained, which is not jammed by errors originating from a heavily failing functional block of the device under test.

An embodiment creates a test apparatus (e.g. a test processor, or a channel module of an automated test equipment, or an automated test equipment) for testing a device under test, wherein the test apparatus is configured to receive a pattern (e.g. a result pattern; e.g. a response pattern) from the device under test, which comprises a sequence of bits (which represent (e.g. in a combined form; e.g. in an interleaved form) information (e.g. test results; e.g. test response information) from (e.g. associated with) a plurality of functional blocks (e.g. “cores”; e.g. result blocks; e.g. functional blocks providing substantially independent test results or test responses) of the device under test). The test apparatus is configured to separate (e.g. treat separately, or record separately) errors within the received pattern associated with different blocks of one or more bits (e.g. to separate errors of different cores) during an execution of a test program (e.g. in order to obtain test results per functional block of the device under test, e.g. per core of the device under test, during the execution of the test program).

This embodiment is based on similar considerations as the embodiments disclosed above, wherein it should be noted that the test apparatus is configured to separate errors within the received pattern associated with different blocks of one or more bits during an execution of the test program. Accordingly, it is not necessary to have a fixed association between bits within the received pattern and functional blocks of the device under test. Rather, the concept is also generally usable, e.g., in case that different blocks of one or more bits within the received pattern comprise a different meaning, indicate different types of errors, or the like. However, it should be noted that the concept may optionally be supplemented by any of the features, functionalities and details disclosed herein.

An embodiment creates a method for testing a device under test. The method comprises receiving a pattern (e.g. a result pattern; e.g. a response pattern) from the device under test, which comprises (e.g. in a combined form; e.g. in an interleaved form) information (e.g. test results; e.g. test response information; e.g. a sequence of bits) from (e.g. associated with) a plurality of functional blocks (e.g. “cores”; e.g. result blocks; e.g. functional blocks providing substantially independent test results or test responses) of the device under test. The method further comprises separating (e.g. treat separately, or record separately) errors within the received pattern associated with different functional blocks of the device under test (e.g. to separate errors of different cores) during an execution of a test program (e.g. in order to obtain test results per functional block of the device under test, e.g. per core of the device under test, during the execution of the test program).

This method is based on the same considerations like the test apparatus discussed herein. Moreover, it should be noted that the method may optionally be supplemented by any of the features, functionalities and details disclosed herein, both individually and taken in combination.

An embodiment according to the invention creates a computer program for performing the method according to claim 37 when the computer program runs on a computer.

### BRIEF DESCRIPTION OF THE DRAWINGS

Embodiments of the present invention will be detailed subsequently referring to the appended drawings, in which:

FIG. 1 shows a block schematic diagram of a test apparatus according to an embodiment of the present invention;

FIG. 2 shows a block schematic diagram of a test apparatus, according to an embodiment of the present invention;

FIG. 3 (Part 1) and FIG. 3 (Part 2) shows a block schematic diagram of a test apparatus according to an embodiment of the present invention;

FIG. 4 shows a schematic representation of a bit stream;

FIG. 5 shows a block schematic diagram of a mapping mechanism which can be used in a test apparatus, according to another embodiment of the present invention;

FIG. 6 shows a schematic representation of a table based separation of error information; and

FIG. 7 shows a flow chart of a method, according to an embodiment of the present invention.

### DETAILED DESCRIPTION OF THE INVENTION

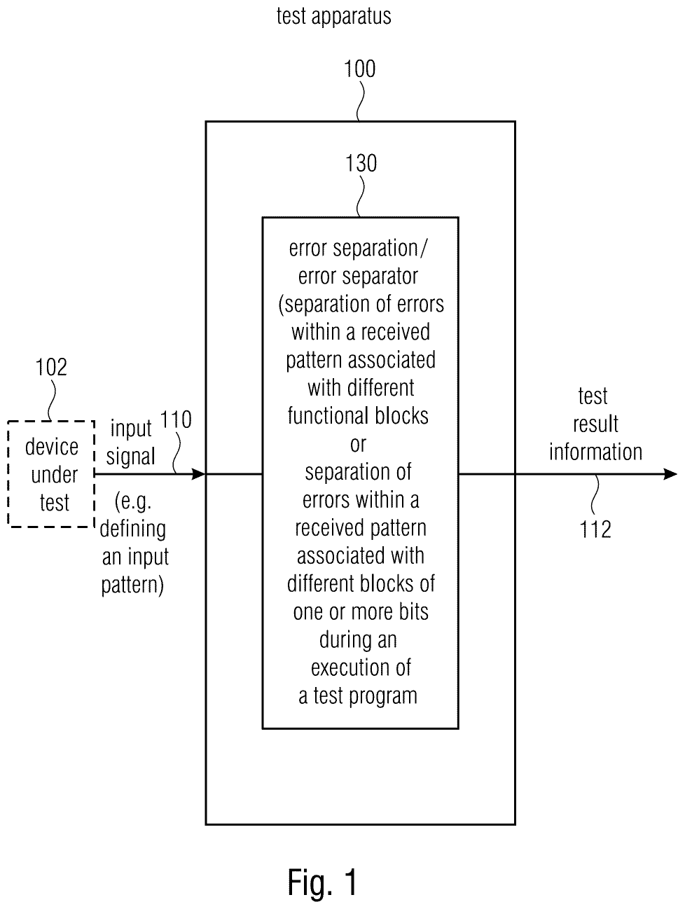

### 1. Test Apparatus According to FIG. 1

FIG. 1 shows a block schematic diagram of a test apparatus 100, according to an embodiment of an invention.

The test apparatus 100 is configured to receive an input signal 110 from a device under test 102, wherein the device under test 102 is typically not part of the test apparatus 100. For example, the input signal 110 may define an input pattern. Moreover, the test apparatus 100 is configured to provide a test result information 112 on the basis of the input signal 110.

It should be noted that the test apparatus 100 may be part of a test system. However, the test apparatus 100 may, for example, be implemented in a test processor, or in a channel module of an automated test equipment or, generally, in an automated test equipment.

The test apparatus 100 is configured to receive a pattern (e.g., a result pattern, e.g., a response pattern) from the device under test. The received pattern typically comprises (e.g., in a combined form; e.g., in an interleaved form) information (e.g., test results; e.g., response information; e.g., a sequence of bits) from (e.g., associated with) a plurality of functional blocks (e.g., “cores”; e.g., result blocks; e.g., functional blocks providing substantially independent test results or test responses) of the device under test. The test apparatus comprises an error separation or an error separator which is configured to separate (e.g., treat separately, and/or forward separately, and/or record separately) errors within the received pattern associated with different functional blocks of the device under test, e.g., to separate errors of different functional blocks or “cores” of the device under test, during an execution of a test program.

Accordingly, the test apparatus 100 may obtain (e.g., separate or different) test results per functional block of the device under test, e.g., per core of the device under test, during the execution of the test program. Thus, the test result information 112 may, for example, describe separate test results associated with different functional blocks or cores of the device under test.

Thus, by separating errors within the received pattern associated with different functional blocks, or by separating errors within the received pattern associated with different blocks of one or more bits, during the execution of the test program, a meaningful test result information can be obtained with moderate implementation effort and with very low latency. Accordingly, the test result information 112 may comprise meaningful information separately describing the integrity of different functional blocks or cores of the device under test during the execution of the test program, e.g., without an extensive buffering of the full received pattern. Accordingly, it has been found that the described concept provides a very good compromise between complexity, test coverage, latency and accuracy. Accordingly, the test apparatus 100 helps to efficiently test devices under test which provide test results of different functional blocks or cores in a multiplexed form (e.g., over a single common pin).

Moreover, it should be noted that the test apparatus 100 may be optionally be supplemented by any of the features, functionalities and details disclosed herein.

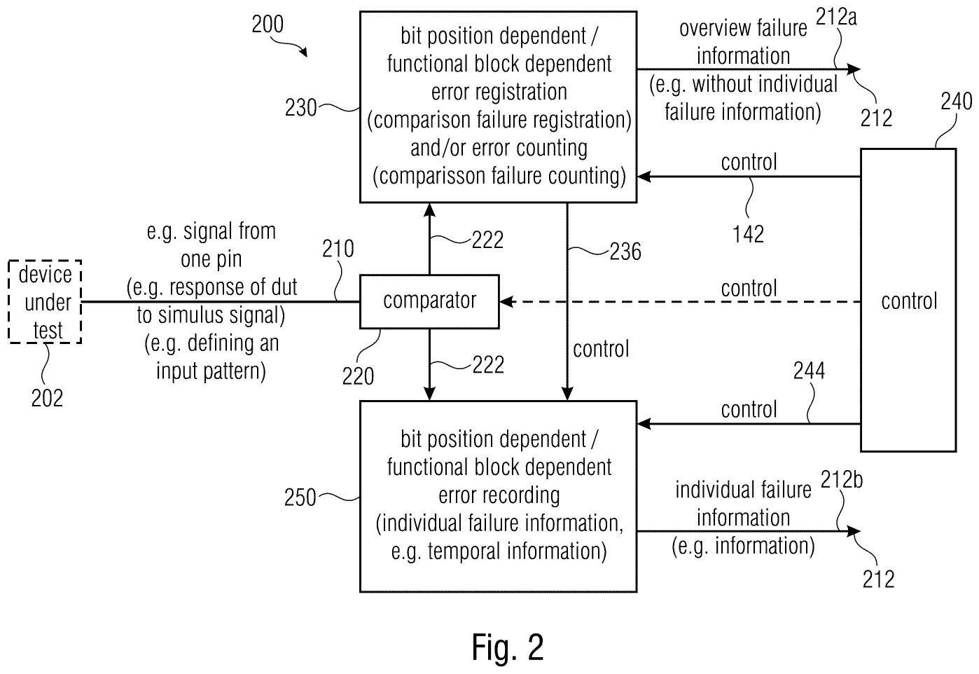

### 2. Test Apparatus According to FIG. 2

FIG. 2 shows a block schematic diagram of a test apparatus 200, according to an embodiment of the present invention. The test apparatus 200 receives an input signal 210 from a device under test 202. For example, the input signal 210 may be a signal from one pin of the device under test. For example, the input signal may be a response of the device under test to a stimulus signal, and the input signal 210 may, for example, define an input pattern.

Moreover, the test apparatus 200 provides a test result information 212 which may, for example, comprise an overview failure information 212a and/or an individual failure information 212b. For example, the overview failure information 212a may separately describe errors associated with different functional blocks of the device under test 202 in a summarized form. For example, the overview failure information 212a may indicate, e.g., for a plurality of functional blocks or for a plurality of groups of functional blocks, which of the functional blocks or of the groups of functional blocks have caused at least one error within the received pattern (e.g., in a pattern determined by the input signal 210). For example, the overview failure information 212a may comprise one binary value per functional block or per group of functional blocks, a respective binary value indicating whether the respective functional block or group of functional blocks of the device under test has caused at least one error within the received pattern. Alternatively or in addition, the overview failure information 212a may comprise separate count values counting numbers of errors generated by different functional blocks or groups of functional blocks of the device under test. Thus, the different count values may, for example, describe errors occurring in different blocks of one or more bits within the received pattern (wherein the different blocks of one or more bits may be associated with different functional blocks or groups of functional blocks of the device under test). Thus, the counter values may, for example, separately indicate how many errors within the received pattern are caused by different functional blocks or groups of functional blocks of the device under test.

Accordingly, the overview failure information 212a may, for example, provide a meaningful information whether different functional blocks have caused an error within the received pattern and/or how many errors different functional blocks (or groups of functional blocks) of the device under test have caused within the received pattern. Accordingly, the overview failure information allows to judge whether different blocks (or groups of functional blocks) have been operating as expected (e.g., if they have not caused any error within the received pattern) or whether the different functional blocks (or group of functional blocks) have not operated in the expected manner (e.g., have caused at least one error within the received pattern).

Moreover, in case a counter information is provided as a part of the overview failure information 212a, it can also be rapidly judged whether one or more functional blocks (or groups of functional blocks) of the device under test have failed heavily, causing a comparatively high number of errors within the received pattern. For example, if it is found that a number of errors within the received pattern caused by a certain functional block (or group of functional blocks) of the device under test reaches or exceeds a predetermined number, it may be concluded by the test apparatus that the functional block (or group of functional blocks) has failed heavily. For example, such an identified functional block (or group of functional blocks) may be excluded from further tests, since it may be assumed that the heavily failing functional block (or group of functional blocks) does not need to be tested further and would complicate or hinder a testing of other functional blocks which do not cause errors within the received pattern or which only cause a small number of errors within the received pattern.

However, it should be noted that the overview failure information 212a, which is typically provided during the execution of a test program, is very helpful for the testing of a device under test, since it is typically provided with low latency and may, in some cases, be sufficient to classify a device under test (e.g. as properly operational or as defective). In particular, the overview failure information may provide an overview over the integrity of different functional blocks (or groups of functional blocks) of the device under test, which may be useful for making test flow decisions and/or a finer classification of the device under test.

The individual failure information 212b, which may be a part of the test result information 212 may, for example, describe individual failures in the received pattern, e.g. in a temporally distinguishable manner. For example, the individual failure information 212b may describe individual failures within the received pattern using a timing information describing a time at which the individual error has occurred (e.g. describing a bit position of the individual error within the received pattern, e.g. using a timestamp or a bit position index, or the like). Typically, the individual failure information describes individual failures within the received pattern, rather than being a full copy of the received pattern, to thereby save memory capacity. For example, the individual failure information may be useful for a detailed analysis of a failure, e.g. to determine which hardware component of the device under test has failed.

The test apparatus 200 comprises a comparator 220, which compares the received pattern (which may be represented by the input signal 210) with an expected pattern (which may, for example, be considered as a reference pattern and which may, for example, be provided by a reference signal generator or a reference pattern generator). The comparator 220 may, for example, provide an error signaling 222 in response to the detection of an error within the received pattern (wherein a deviation between a bit of the received pattern and a bit of a reference pattern may be considered as an error). For example, the comparator may provide the error signaling 222 for every error between the reference pattern and the received pattern, but in some cases, the comparison and/or the provision of the error signaling 222 and/or the forwarding of the error signaling 222 may be selectively enabled and/or selectively disabled for different blocks of one or more bit positions within the received pattern (e.g. to thereby separate errors associated with different functional blocks (or groups of functional blocks) of the device under test.

The test apparatus 200 also comprises an overview failure information determination/overview failure information determinator 230 which receives the error signaling 222 from the comparator 220 and which provides the overview information 212. The overview failure information determination 230 may, for example, be configured to perform a bit position dependent/functional block dependent error registration and/or a bit position dependent/functional block dependent error counting. For example, the error registration may perform a comparison failure registration, wherein comparison failures in different blocks of one or more bits of the received pattern may be registered in different error registers. Similarly, the error counting may perform a comparison failure counting, wherein comparison failures occurring in different blocks of one or more bits of the received pattern may be counted by different counters. For example, the overview failure information determination may receive control signals from a control 240, wherein the control signals 242 may, for example, indicate to the overview failure information determination which error register should be activated by an error signaling or which error counter out of a plurality of error counters should be incremented in response to a failure signaling 222. The control 240 may, for example, provide one or more control signals 242 in dependence on an á priori knowledge which bit positions within the received pattern are associated with which functional block (or group of functional blocks) of the device under test, taking into account the timing of the input signal 210. Accordingly, the overview failure information determination can separately register and/or count comparison failures caused by different functional blocks (or groups of functional blocks) of the device under test. Thus, a meaningful overview failure information can be generated.

Moreover, the test apparatus 200 comprises an individual failure information recording/individual failure information recorder 250, which may receive the error signaling 222 from the comparator 220 and which may also receive one or more control signals 244 from the control 240. The individual failure information recording/individual failure information recorder provides the individual failure information 212b. For example, the individual failure information recording/individual failure information recorder 250 may perform a bit position dependent/functional block dependent error recording, to thereby obtain the individual failure information 212b. The individual failure information 212b may, for example, comprise temporal information describing a temporal position of a comparison failure. However, the individual failure information recording/recorder 250 may be controlled in such a manner that comparison failures (comparison errors) associated with different functional blocks of the device under test are recorded separately, and/or such that a recording of individual failure information can be activated and/or deactivated separately for failures associated with different functional blocks of the device under test. For example, the activation and/or deactivation of the recording of individual failure information may be controlled by the control signal 244 provided by the control 240. Accordingly, it is possible to selectively record individual failure information associated with different functional blocks of the device under test, wherein, for example, a recording of individual failure information can be disabled for failures caused by one or more certain functional blocks of the device under test. Accordingly, it is possible to focus the recording of individual failure information on individual failure information associated with one or more functional blocks of the device under test currently of interest. Alternatively, or in combination, a recording of individual failure information can be selectively suppressed for failures originating from one or more certain functional blocks of the device under test, for example for one or more certain functional blocks of the device under test that fail heavily (and therefore produce an excessive number of failures).

For example, a recording of individual failure information may be automatically disabled by the test apparatus (e.g. by the control 240) for a certain functional block of the device under test if the overview failure information determination 230 determines that this certain functional block of the device under test has generated a number of errors in the received pattern which reaches or exceeds a predetermined threshold value. Thus, it may, for example, be ensured that only a predetermined maximum amount of individual failure information is recorded for a given functional block of a device under test (or for all functional blocks of the device under test). This blocking of the further recording of individual failure information for heavily failing functional blocks of the device under test may, for example, be controlled by a control signal 244 provided by the overview failure information determination.

Accordingly, the test apparatus 200 can separate errors within the received pattern associated with different functional blocks of the device under test during an execution of a test program. The overview failure information 212a may, for example, indicate separately for different functional blocks of the device under test, a failure information indicating whether different functional blocks of the device under test have caused a failure in the received pattern and/or how many failures the different functional blocks of the device under test have caused. Moreover, the apparatus allows to provide the individual failure information, wherein, due to the separation of errors within the received pattern associated with different functional blocks, it can be determined (set) for which errors the individual failure information 212b is recorded. For example, the recording of individual failure information can be selectively enabled and/or disabled for errors caused by certain functional blocks of the device under test. Accordingly, an amount of individual failure information can be kept reasonably small, thereby reducing the memory requirements and/or preventing a jamming of the available memory (e.g. by disabling a recording of errors generated by heavily failing functional blocks of the device under test).

Thus, the test apparatus provides for a very efficient testing of the device under test, wherein the overview failure information, which is available with little delay, may be helpful for classifying a device under test and may also be helpful for making test flow decisions. Furthermore, the selective recording of individual failure information may help to help to save test resources and to efficiently get meaningful test results even in the case that one or more functional blocks of the device under test are heavily failing.

Moreover, it should be noted that the test apparatus 200 may optionally be supplemented by any of the features, functionalities and details disclosed herein, both individual and taken in combination.

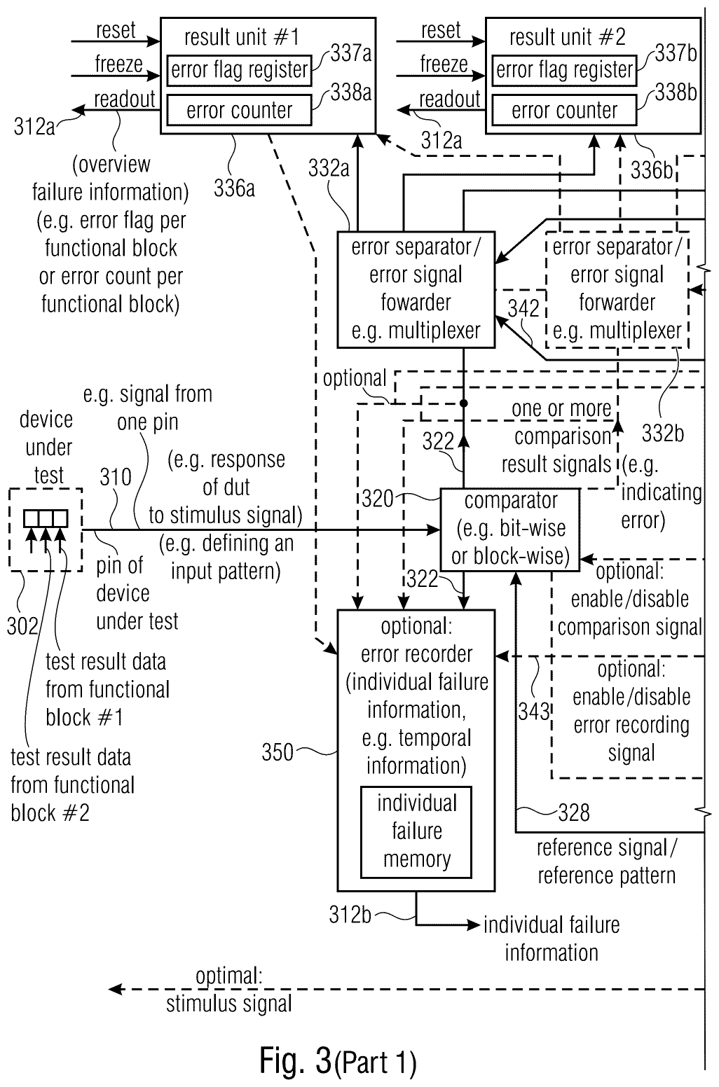

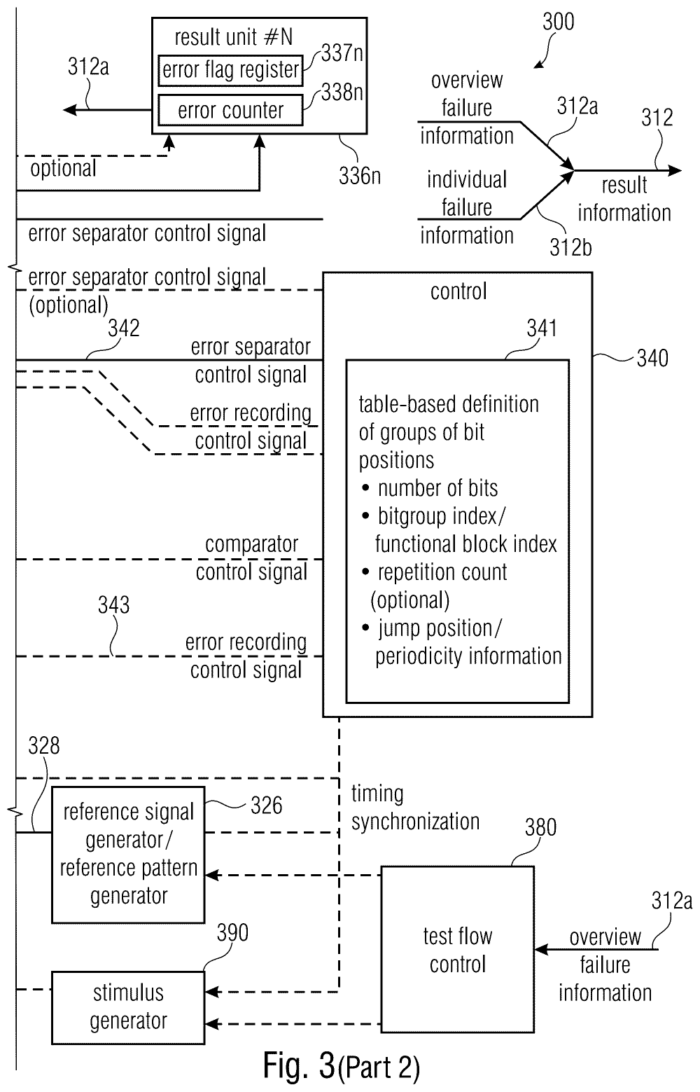

### 3. Test Apparatus According to FIG. 3

FIG. 3 shows a block schematic diagram of a test apparatus 300, according to another embodiment of the present invention.

The test apparatus 300 according to FIG. 3 is configured to receive an input signal 310 and to provide, on the basis thereof, a result information 312 which may for example, comprise an overview failure information 312a and an individual failure information 312b. It can be assumed here that the device under test 302 provides the input signal 310 of the test apparatus 300. The input signal 310 may, for example, be a signal which is output by the device under test 302 at a pin of the device under test 302. For example, the input signal 310 may be a digital signal, wherein test result data from a first functional block of the device under test is included in the input signal 310 in a first block of one or more bit positions and wherein test result data from a second functional block of the device under test 302 is included in a second block of one or more bit positions. In other words, test result data from different functional blocks of the device under test 310 may be multiplexed (e.g., time multiplexed) in the input signal 310, e.g., using a predetermined multiplexing rule. Thus, the input signal 310 may, for example, be a signal originating from one pin of the device under test and may, for example, represent a response of the device under test to a stimulus signal which may also be provided by the test apparatus. For example, the input signal 310 may define an input pattern, which is also designated herein as a received pattern.

The input signal 310 may optionally undergo some pre-processing in the test apparatus, which is not shown in FIG. 3. The pre-processing may, for example, comprise a conversion of the actual analogue input signal 310 into a digital signal, a time discretisation (e.g., a sampling) and the like.

Accordingly, for example, a time discretised digital version of the input signal may be provided to a comparator 320. The comparator 320 also receives a reference signal or a reference pattern from a reference signal generator/reference pattern generator 326. Thus, the comparator may compare the input signal 310 (or a digitized and time-digitized version thereof) with the reference signal 328 provided by the reference signal generator 326, or the comparator 320 may compare a received pattern (which is defined by the input signal 310) with a reference pattern that is provided by the reference pattern generator 326. For example, the comparator 320 may bit-wisely compare the input signal (or a digitized and time-discretized version thereof) with a corresponding reference signal, or the comparator may block-wisely compare a received pattern with a reference pattern.

It should be noted that in the present concept, both a bit wise comparison between the input signal 310 (or a digitized and time-digitized version thereof) and the reference signal and a block-wise comparison between a received pattern and a corresponding reference pattern may be used to identify errors within the received pattern (wherein it is assumed that a difference between a bit of the input signal and a bit of the reference signal indicates an error within the received pattern and that a difference between one or more bits in the received pattern and one of the bits in the reference pattern also indicate an error in the received pattern). In other words, it should be noted that the input signal received by the test apparatus may be considered as a representation of a received pattern.

Worded yet differently, the detection whether a bit of the input signal received by the test apparatus deviates from a corresponding bit of the reference signal is one possibility to detect an error in the received pattern. However, a block-wise comparison between a block of bits of the input signal 310 and a block of bits of the reference pattern provided by the reference signal generator 326 is another concept to identify an error within the received pattern. Generally speaking, it should be noted that the temporal evolution of the input signal 310 defines a received pattern, such that the detection of an error in the received pattern corresponds to the detection of a deviation of the input signal from the corresponding reference signal.

Moreover, it should be noted that the received pattern, received by the test apparatus, may be a bit pattern in which test result data from different functional blocks of the device under test are time-multiplexed (according to a predetermined time-multiplexing rule).

The comparator provides an error signal 322, wherein the error signal 322 may, for example, indicate a deviation between a bit of the received signal and a bit of the reference signal or, equivalently, an error within the received pattern.

The error signal may, for example, be evaluated for the determination of the overview failure information. For example, the test apparatus 300 may comprise one or more error separators/error signal forwarders 332a, 332b (wherein, for example, a usage of a plurality of error separators/error signal forwarders may be advantageous in case that a plurality of error signals are generated simultaneously or in close temporal succession), and the test apparatus 300 may also comprise a plurality of result units 336a, 336b, 336n. For example, the error signal separator 332a may receive the error signal 322 and forward the error signal 322 to one of the result units 336a, 336b, 336n in accordance with a control information (e.g. in accordance with an error separator control signal 342). For example, the error separator 332a may be considered as an error signal forwarder and may, for example, be implemented using an multiplexer. Accordingly, the error separator 332a may decide to which of the result units 336a, 336b, 336c an error signal is forwarded.

The decision to which of the result units 336a, 336b, 336n the error signal is forwarded may be based on a determination to which functional block of the device under test an erroneous bit in the received pattern causing the activation of the error signal 322 is associated. For example, if the erroneous bit in the received pattern causing the activation of the error signal 322 is associated with (or caused by) a first functional block of the device under test, the error signal 322 may be forwarded to the first result unit 336a. In contrast, if the erroneous bit within the received pattern causing the activation of the error signal 322 is associated with (or caused by) a second functional block of the device under test, the error signal 322 may be forwarded to the second result unit 336b. Furthermore, generally speaking, if the activation of the error signal 322 is caused by an erroneous bit in the received pattern that is associated with (or caused by) a n-th functional block of the device under test, the error signal 322 may be forwarded to the n-th result unit 336n by the error separator 332a.

The respective result units 336a, 336b, 336n may, for example, be configured to register the activation of an error signal which is forwarded to the respective result unit. For example, the first result unit 336a may comprise an error flag register 337a and/or an error counter 338a. Accordingly, if the error signal 322 is forwarded to the first result unit 336a, the error flag register 337a of the first result unit 336a may be set, thereby indicating that an error in the received pattern was caused by the first functional block of the device under test (wherein, effectively, the first result unit 336a is associated with the first functional block of the device under test). Alternatively or in addition, the error counter 338a of the first result unit 336a will be incremented if an error signalling (i.e., an active error signal 322) is forwarded to the first result unit 336a. Accordingly, the error counter 338a of the result unit 336a may count a number of errors within the received pattern that are associated with the first functional block of the device under test. Thus, the result unit 336a may, for example, register whether there has been an error within the received pattern caused by the first functional block and/or how many errors there are within the received pattern caused by the first functional block of the device under test. Similarly, there error flag register 337b of the second result unit 336b will be activated when (an active) error signal is forwarded to the second result unit 336b via the error separator 332a. In other words, the error flag register 337b will be set in response to an error in the received pattern which is associated with (or caused by) the second functional block of the device under test. Alternatively or in addition, the error counter 338b of the second result unit 336b will be incremented in response to the presence of an error in the received pattern which is associated with (or caused by) the second functional block of the device under test.

Accordingly, a respective result unit registers and/or counts errors in the received pattern associated with a corresponding functional block of the device under test. However, alternatively, a respective result unit may also register and/or count errors in the received pattern caused by a group of functional blocks in the device under test. In other words, it is not necessary that there is a 1-to-1 association between functional blocks of the device under test and result units. Rather, a plurality of functional blocks of a device under test may be associated with a single result unit in some cases (e.g. if a number of result units is smaller than a number of functional blocks in the device under test).

To conclude, using the selective forwarding of an error signal to one of the result units, controlled, for example, by the error separator 332a or by a control unit 340 providing an error separator control signal 342, errors in the received pattern associated with different functional blocks of the device under test can be registered and counted in different result units. Consequently, the error flag register of a respective result unit indicates whether a functional block of the device under test associated with the respective result unit has caused an error in the received pattern. Similarly, an error counter of a respective result unit indicates how many errors within the received pattern a functional block of the device under test associated with the respective result unit has caused. Accordingly, the different result units provide information about an integrity of the different functional blocks of the device under test. For example, the respective error flag registers of the result units indicate whether or not a respective functional block of the device under test has caused one or more errors in the received pattern, and the error counters of the respective result units indicate how many errors a respective functional block of the device under test has caused in the received pattern.

Thus, the information of the error flag registers and/or of the error counters in the result units can be used as an overview failure information 312a.

It should be noted that the result units may have functionalities to reset the error flag register and/or the error counter, and/or to freeze a state of the error flag register and/or of the error counter and to read out a state of the error flag register and/or a count value of the error counter. For example, the read out values (e.g., a binary value of the error flag register and/or a numeric value of the error counter) may form the overview failure information. Thus, the overview failure information 312a provides a fast overview which of the functional blocks of the device under test caused one or more errors in the received pattern. Moreover, the overview failure information 312a may also provide a fast overview which of the functional blocks of the device under test fail heavily, i.e., generate a large number of errors in the received pattern.

The test apparatus 300 also comprises (optionally) an error recorder 350 which may provide the individual failure information 312b. For example, the error recorder 350 may record (e.g., store in a memory) an individual failure information which describes an error in detail and which typically comprises a temporal information precisely defining a timing of the error. For example, the individual failure information may describe a plurality of errors in the received pattern in detail, including the precise time (or bit position) at which an error has occurred. Since it is typically assumed that the received pattern comprises only a comparatively small number of errors, the storage of the individual error information is typically much more memory efficient than the storage of the full received pattern for a later evaluation. However, the individual error information typically allows the user of the test apparatus to analyse in detail the error in the device under test. Thus, the individual failure information typically allows to more precisely figure out which type of error has occurred in the device under test, while the overview failure information 312a typically only allows to recognize that an error has occurred in a functional block of a device under test and how heavily the functional block of the device under test has failed.

However, the test apparatus 300 may be configured such that the recording of individual failure information can be selectively enabled and/or disabled for errors originating from certain functional blocks of the device under test. For example, the control 340 may provide one or more error recording control signals 343 which selectively enable and/or disable a recording of individual failure information for errors within the received pattern that are associated with certain functional blocks of the device under test. For example, when the control 340 finds that a currently analysed bit position of the received pattern is associated with a functional block of the device under test for which an individual failure information should be recorded, the control 340 may enable the recording of the individual failure information and/or may enable the forwarding of the failure signal 322 to the error recorder 350. On the other hand, if the control 340 finds that a currently analysed (or processed) bit position is associated with a functional block of the device under test for which no individual error information should be recorded, the control 340 may provide one or more control signals to disable the error recording by the errors recorder 350 or to disable a forwarding of the error signal 320 to the error recorder 350 (thereby preventing a recording of the individual failure information).

Thus, the control 340 may track to which functional block of the device under test a current bit positon, which is currently processed by the comparator 320, is associated, and may, accordingly control the error separator 332a, to forward a possible error signal to an appropriate result unit, and may also enable or disable the recording of the individual failure information. Accordingly, it can be avoided to record individual failure information for one or more functional blocks of the device under test. This is particularly advantageous if it has been found before that one or more functional blocks of the device under test fail heavily, i.e., provide a very large number of errors within the received pattern. In such a case, by disabling the recording of individual failure information in the received pattern originating from the heavily failing functional block(s) of the device under test, a jamming of the error recorder or of the individual failure memory of the error recorder, can be prevented.

Moreover, it should be noted that, in the test apparatus 300, the recording of individual failure information may, for example, be automatically disabled for a functional block of the device under test for which a result unit recognizes an excessive number of failures. For example, if an error counter of a result unit associated with a certain functional block of the device under test reaches or exceeds a predetermined threshold value, the recording of individual failure information can be automatically disabled for bit positions associated with the certain heavily failing functional block of the device under test. A simple control logic may be used for this purpose which recognizes that an error counter of a certain result unit has reached or exceeded a predetermined threshold value and which deactivates the recording of individual failure information for associated blocks of one or more bits of the received pattern.

It should be noted that a control 340 may be used to provide control signals for the error separator 332a and also for the enabling and disabling of the recording of the individual failure information by the error recorder 350. For example, the control 340 may be in timing synchronization with a stimulus generator which provides a stimulus signal to the device under test, with the reference signal generator 326 and with the comparator 320. Accordingly, the control 340 may, for example, operate in temporal synchronism with a bit clock of the input signal 310. Accordingly, the control unit 340 may count the received bits of the input signal 310 and may therefore be able to operate in synchronism with bits of the received signal 310. For example, the control unit may count received bits of the input signal 310 to thereby conclude to which functional blocks of the device under test the individual bits are associated. For example, the control 340 may comprise a table based definition of groups of bit positions within the input signal 310. The table-based definition may, for example, describe lengths of different groups (or blocks) of bits within the input signal 310. For example, the table-based definition of groups of bit positions may indicate that the input signal starts with a number of “unreliable” bits that should be discarded. The table-based definition of groups of bit positions used by the control 340 may then specify that the next group of bits is associated with a first functional block of the device under test, and that a subsequent group of bits is associated with a second functional block of the device under test. Lengths of the different groups of one or more bits may also be defined in the table-based definition of the groups of bit positions.

Moreover, the table-based definition of groups of bit positions may also comprise an information about repetitions of groups of bits (e.g., a repetition count). For example, the table-based definition of groups of bit positions may comprise a jump position information or a periodicity information which may, for example, define a repetition of a sequence of groups of bit positions. For example, the jump position information may indicate to jump back to a certain row of the table-based definitions to thereby define a repetition of a definition of an association of groups of bit positions with functional blocks of the device under test. Accordingly, a periodicity of the groups of bit positions within the input signal 310 may be defined by the table.

Accordingly, the control 340 may be able to determine a functional block index for every bit within the received pattern. In other words, the control 340 may determine, for each bit within the received pattern, to which functional block of the device under test this bit is associated (wherein some bits of the received pattern may actually be associated with no functional block of the device under test, which may, for example, be indicated by a “special” functional block index signalling no association). Thus, for example, a functional block index, including an index indicating no association, may be provided by the control 340 for each bit (bit position) of the received pattern. This index may, for example, be used to control the error separator 332a, since the index may define to which result unit 336a, 336b, 336n an error signal (or an error signalling) should be forwarded. Moreover, the index which is determined by the control 340 may also be used to determine whether an individual failure information 312b should be recorded by the error recorder 350 in case that a respective bit is erroneous. For example, it may be defined that individual failure information should be recorded for erroneous bits (bit positions) to which the control 340 has associated certain index values, while individual failure information should not be recorded if other index values are associated with erroneous bits (bit positions). Thus, the control 340 may distinguish different groups of one or more bit positions, e.g., based on the table-based definition of groups of bit positions and making use of a timing synchronization with the stimulus generator, the reference signal generator and the comparator, and the control 340 may control the generation of the overview failure information and the recording of the individual failure information in dependence on the determination in which a group of one or more bits (defined in the table-based definition of groups of bit positions) an error occurs. Consequently, the test apparatus 300 may obtain the overview failure information 312a indicating the integrity of different functional blocks of the device under test, and the test apparatus may obtain the individual failure information 312b for selected functional blocks of the device under test.

Moreover, it should be noted that the test apparatus comprises a test flow control 380 which may, for example, determine which test programs are executed. For example, the test flow control may control the stimulus generator and the reference signal generator, but the test flow control may also control other components of the test apparatus. However, the test flow control 380 may make decisions on the execution of the test flow in dependence on the overview failure information 312a. In this regard, it should be noted that the overview failure information 312a is available with little latency, since the overview failure information 312a is typically determined during the execution of a test program. Accordingly, the test flow control 380 can quickly recognize on the basis of the overview failure information which functional blocks of the device under test appear to be error-free and which functional blocks of the device under test fail or fail heavily. Accordingly, the test flow control 380 may decide which test programs should be executed, taking into account the information about the functional status of different functional blocks of the device under test which is provided by the overview failure information. Accordingly, a particularly efficient test flow can be implemented, since, for example, a further testing of heavily failing functional blocks can be avoided or since, for example, a more detailed analysis of heavily failing functional blocks can be performed.

Naturally, it is also possible to modify test parameters like a supply voltage, a clock frequency, or the like, in response to the overview failure information.

To conclude, the test apparatus 380 provides a significant amount of information about the device under test in a very efficient and fast manner. A jamming of the individual failure information recording can also be prevented and the individual failure information recording can be directed to one or more functional blocks of special interest. The test flow control can also be optimized by making use of the overview failure information.

Moreover, it should be noted that the functionalities of the apparatus 300 may be fully or partly implemented in hardware to allow for a particularly fast reaction time. However, it should be noted that at least some of the functionalities of the test apparatus 300 may optionally be implemented in software.

Moreover, it should be noted that the test apparatus may optionally comprise a plurality of error separators/error signal forwarders. This may, for example, be advantageous if the comparator performs a block wise comparison between a block of bits of the input signal and a block of bits of the reference signal. In this case, a parallel processing of multiple error signals arising from said block wise comparison may be performed. However, it should be noted that it is not necessary to have more than one error separator/error signal forwarder.

Furthermore, it should be noted that the functionalities described here may also be implemented using different functional blocks. For example, the functionality of the error separator/error signal forwarder may be implemented in the result units, for example using a selective enable mechanism.

Similarly, it should be noted that different actual implementations could be used for selectively enabling and disabling the recording of individual failure information. However, it appears to be important to have a control mechanism which tracks to which group of one or more bits the currently considered bits of the received pattern is associated (which corresponds to a tracking to which functional blocks the bits of the received pattern are associated). By having knowledge to which groups of bits (or, equivalently, to which functional blocks of the device under test) the bits of the received pattern are associated, the determination of the overview failure information and/or of the individual failure information can be controlled efficiently and accurately.

Moreover, it should be noted that the test apparatus 300 according to FIG. 3 may optionally be supplemented by any of the features, functionalities and details disclosed herein.

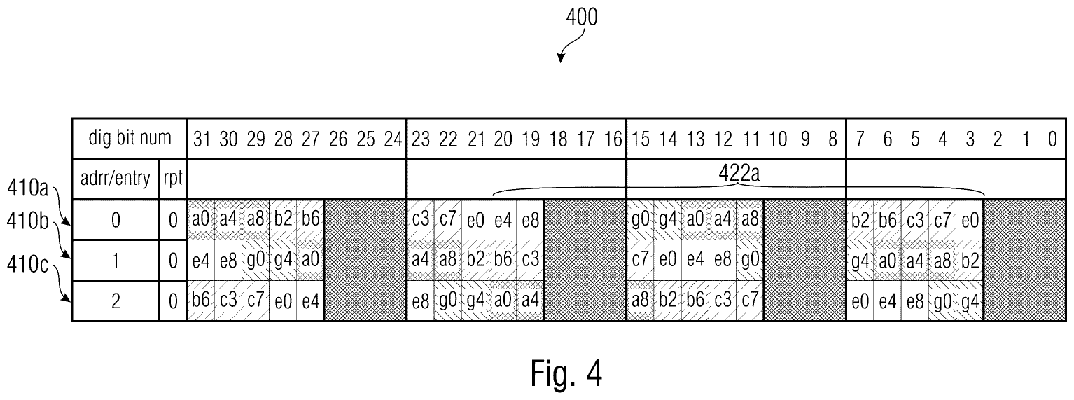

### 4. Bitstream According to FIG. 4

FIG. 4 shows a schematic representation of an example bitstream which is provided by a device under test. The bitstream is designated with 400.

The bitstream is provided by the device under test, and may constitute the received pattern which is received by the test apparatus disclosed herein.

For example, the bitstream may be logically separated into blocks of 32 bits, wherein each line 410a, 410b, 410c shows a sequence of 32 bits originating from a different pin of the device under test. For example, bits 0-2, 8-10, 16-18 and 24-26 may not be associated with functional blocks of devices under test, but may, for example, provide general information, like synchronization information, parity information, undefined information or determined fixed values. However, bit positions 3-7, 11-15, 19-23 and 27 to 31 may provide information associated with different functional blocks of the device under test. For example, the bit positions 3-7, 11-15, 19-23 and 27-31 may comprise test results of different functional blocks of the device under test.

For example, different functional blocks of a device under test may be stimulated by one or more stimulus signals provided from the test apparatus, wherein the stimulus signals may, for example, be input into a scan chain of the device under test and/or may be input at input terminals (e.g. of the device under test). However, the result information of the functional blocks of the device under test may, for example, be based on internal signals of the device under test (or of the functional blocks of a device under test), which are multiplexed together into the bit stream 400.

For example, as can be seen in a first line 410a, a sequence of bits, which is designated to with 422a, may start with a bit e0 from a (first) functional block e of the device under test, may continue with two bits c7, c3 from a (second) functional block c of the device under test, may continue with two bits b6, b2 from a (third) functional lock b of the device under test, may continue with three bits a8, a4, a0 from a (fourth) functional block a of the device under test, may continue with two bits g, g4, g0 from a (fifth) functional block g of the device under test and may end with two bits e8, e4 from the first functional block e of the device under test. Accordingly, the sequence 422a may comprise 12 bits originating from five different functional blocks of the device under test (three bits from functional block e, two bits from functional block c, two bits from function block b, three bits from functional block a and two bits from functional block g). As can be seen, bits originating from different functional blocks of the device under test (which may, for example, represent states of internal signals of the respective functional blocks) are interleaved into a common signal. For example, the different bit positions may be associated with different internal signals of the functional blocks of the device under test, such that the actual values in the different bit positions may actually vary over time, e.g., in accordance with a “stimulation” of the different functional blocks of the device under test. Thus, for example, a bit at bit position e0 may describe a state of a certain internal signal of the first functional block e and a bit at bit position e8 may describe a state of another internal signal of the first functional block e, and a bit at bit position e4 may describe yet another internal signal of the functional block e. Similarly, bits at bit positions c7 and c3 may describe different internal signals of the functional block c, and so on.

However, the allocation of positions may continue with some periodicity. For example, bit position 21 of the group of 32 bits shown in the first line of line 410a may again represent the same internal signal of the device under test which was signalled at bit position 3 within the first block of 32 bits (/but at a later instance of time). Moreover, the following bit positions 22, 23, 27, 28, 29, 30 and 31 may describe the same internal signals of the respective functional blocks which have been represented at positions 4, 5, 6, 7, 11, 12 and 13.

However, similar signals may be present at different pins of the device under test, as can be seen in a second line 410b and in a third line 410c.

Generally speaking, it should be noted that a device under test typically provides a signal that serves as an input signal of the test apparatus and which comprises a periodicity. The signal provided by the device under test at an input of the test apparatus generally comprises an repetitive sequence of bits that describe a variety of signals within the device under test, which are typically internal signal of the functional blocks of the device under test, but which could also include signals that are externally available.

However, the test apparatus is configured to track which bits of the sequence of bits belong to which functional blocks of the device under test (or which bits of the received signal or “received pattern” belong to which group of functional blocks) and can therefore separate errors belonging to different functional blocks or groups of functional blocks of the device under test. For this purpose, the test apparatus may be configured to retrace an allocation, using a rule defining which bits (or bit positions) in the received signal or in the received pattern are associated with which functional blocks of the device under test, e.g., using a table based definition of the association rule.

For example, the table based description of the association rule may define groups of bits by their length (one or more bits) and by an index designating their associated functional block or their associated group of functional blocks. Moreover, the table based definition of the association rule may optionally comprise the definition of periodicities and the definition of bits which are not associated with any of the functional blocks of the device under test (like, for example, bit positions 0-2, 8-10,16-18 and 24-26).

However, it should be noted that the bitstream 400 as shown in FIG. 4 should be considered as an example only, and that different formats of the bitstream would also be possible.

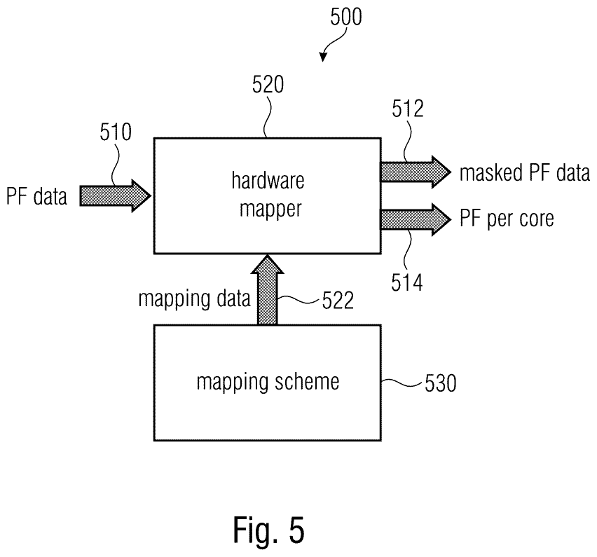

### 5. Mapping Mechanism According to FIG. 5

FIG. 5 shows a block schematic diagram of a mapping mechanism, which can be used in test apparatuses according to the present invention. For example, the mapping mechanism 500 according to FIG. 5 may optionally be used in any of the test apparatuses discussed herein, for example in the test apparatus 100 according to FIG. 1, in the test apparatus 200 according to FIG. 2, or in the test apparatus 300 according to FIG. 3. However, the mapping mechanism 500 may also constitute an independent embodiment which can be used on its own.

The mapping mechanism 500 according to FIG. 5 is configured to receive pass/fail-data (PFD) 510.

Moreover, the mapping mechanism 500 provides masked pass/fail data 512 and/or pass/fail data per core 514 on the basis of the pass/fail data 510. For example, the mapping mechanism 500 comprises a hardware mapper 520 which receives the pass/fail data 510 and provides, on the basis thereof, the masked pass/fail data 512 and/or the pass/fail data per core 514. The hardware mapper 520 receives mapping data 522 from a mapping scheme 530.

For example, the mapping scheme 530 may define how the pass/fail data 510 should be mapped by the hardware mapper 520 onto masked pass/fail data 512 and/or onto pass/fail data per core 514. For example, the mapping scheme 530 may define which pass/fail data 510 should be blocked (or omitted) in the masked pass/fail data 512 and/or may define which of the pass/fail data 510 should be taken over into the masked pass/fail data 512. For example, the mapping scheme 530 may define that certain bits of the pass/fail data 510 may be taken over into the masked pass/fail data 512, or the mapping scheme 530 may define that certain bits of the pass/fail data 510 should be blocked and should not be taken over into the masked pass/fail data 512.

The mapping scheme 530 may, for example, comprise a definition of bit positions (e.g. of groups of bits) of pass/fail data 510 which should be taken over in the masked pass/fail data 510 and/or definition of bit positions (e.g. groups of bits) which should not be taken over from the pass/fail data 510 into the masked pass/fail data 512. For example, the hardware mapper 520 may comprise a controllable transmission gate to obtain the masked pass/fail data 512 on the basis of the pass/fail data 510, wherein the controllable transmission data may be controlled by the mapping data 522.

Moreover, the hardware mapper 520 may distribute the pass/fail data 510 (e.g. to a plurality of different outputs), to thereby obtain the pass/fail-data-per-core or pass/fail-signals-per-core 514. For example, the hardware mapper may forward a part of the pass/fail data 510 to a first output and may forward another part of the pass/fail data 510 to another output. For example, the hardware mapper 520 may comprise a multiplexer to selectively forward the pass/fail data 510 to a respective output, wherein the multiplexer may, for example, be controlled by the mapping data 522. Accordingly, one or more bits of the pass/fail data associated with (e.g. originating from) a first functional block (e.g. core) of the device under test may be forwarded to a first output by the hardware mapper, and the hardware mapper 510 (or a the multiplexer thereof) may forward one or more other bits of the pass/fail data 510 associated with another functional block (e.g. core) of the device under test to another output. Accordingly, the pass/fail data 510 may be separated into pass/fail data associated with different functional blocks (e.g. cores) of the device under test, such that, for example, different bits of the pass/fail data 510 may be forwarded to different outputs for separate pass/fail-data-per-core signals. This multiplexing may also be controlled by the mapping data 522, that are derived from the mapping scheme 530.

Just as an example, the mapping mechanism 500 may, for example, be configured to forward pass/fail data which are based on bits e0, e4, e8, c3, c7, b2, b6, g0 and g4 into the masked pass/fail data 512, but may, for example, block pass/fail data originating from bits a0, a4 and a8, such that pass/fail data which are based on bits a0, a4, a8 are not included in the masked pass/fail data 512. This may be helpful, for example, if functional block (or a core) a is heavily failing, (e.g. generates a large number of failing bits). Accordingly, the amount of pass/fail data indicating an erroneous bit can be kept reasonably small.

Moreover, the mapping mechanism 500 may, for example, be configured to selectively forward pass/fail data which are based on bits a0, a4 and a8 to a first output (a first pass/fail-data-per-core output), to forward pass/fail data that are based on bits b2 and b6 to a second output (to a second pass/fail-data-per-core output), to forward pass/fail data originating from bits c3 and c7 to a third output (e.g. to a third pass/fail-data-per-core output), to forward pass/fail data originating from bits e0, e4 and e8 to a fourth output (e.g. to a fourth pass/fail-data-per-core output), and to forward pass/fail data originating from bits g0 and g4 to a fifth output (e.g. a fifth pass/fail-data-per-core output). Accordingly, pass/fail data that are based on bits within the received pattern associated with different functional bocks (cores) of the device under test may be forwarded to different outputs of the hardware mapper 520, such that errors associated with different functional blocks (e.g. cores) of the device under test can be separately registered and/or counted.

Moreover, it should be noted that the hardware mapper 520 may, for example, take over the functionality of the error separator/error signal forwarder 332a and/or of the selective forwarding of error signals to the error recorder 350. For example pass/fail data 510 may correspond to the one or more error signals 322, and the masked pass/fail data 512 may, for example, correspond to one or more masked error signals that trigger the error recorder 350. Moreover, the pass/fail signals per core 514 may, for example, correspond to the error signals which are selectively forwarded to the result units 336a, 336b, 336n. The mapping scheme 530 may, for example, be evaluated by the control 340, and the mapping data 522 may, for example, correspond to the error separator control signal 342 and/or to the error recording control signal 343. For example, a multiplexing functionality implemented in the hardware mapper 520 may correspond to a multiplexing functionality implemented in the error separator/error signal forwarder 332a.

A masking functionality implemented in the hardware mapper 520 may, for example, correspond to a selective forwarding of one more error signals from the comparator 320 to the error recorder 350. The evaluation of the mapping scheme 530 may, for example, be performed by the control 340, wherein the mapping scheme 530 may, for example, correspond to the table-based definition of groups of bit positions shown in FIG. 3.

Moreover, it should be noted that the mapping, which is defined by the mapping scheme 530, should be periodic after X cycles. However, the functionality of the mapping is typically dependent on the mapping scheme used (wherein, in some embodiments, a table-based mapping scheme may be used).

To conclude, FIG. 5 shows a block diagram of a mapping mechanism which can be used in any of the embodiments disclosed herein.

Moreover, it should be noted that the mapping mechanism of FIG. 5 may optionally be supplemented by any of the features, functionality and details disclosed herein.

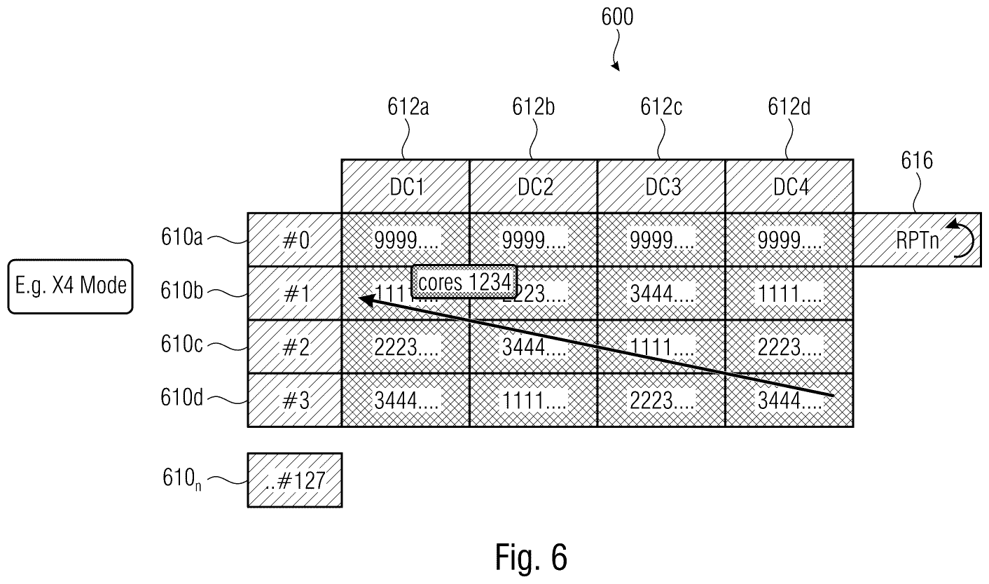

### 6. Result Per Core Mapper and Mapping Scheme According to FIG. 6

In the following, a result per core mapper (RPC, RPCM) will be described taking reference to FIG. 6. It should be noted that the result per core mapper described in the following may optionally be used in any of the embodiments disclosed herein.

A result per core mapper (RPC) may be configured to look at the compare results (e.g. to evaluate the compare results), but (for example) with a granularity of four device cycles (e.g. with a granularity of four bits or with a granularity of four bytes, e.g. if a device cycle provides four bytes). However, different lengths of the device cycles can be used, and a different number of device cycles processed by the result per core mapper may also be used. Also, a result-per-core mapper may optionally operate on single bits.

Regarding this issue, it should be noted that, if a mapping description does not end at the end of a mapper line, it should be rolled out (or, in some cases, needs to be rolled out) until it fits.

For example, if it is desired (or needed) to initially ignore a number of test processor cycles, we can map to an unused core. For example, an unused core index may be associated with such data (associated with test processor cycles to be ignored).

Taking reference now to FIG. 6, a mapping scheme and a table-based definition of the mapping scheme will be described. For example, the mapping scheme is used in a so-called “X4 mode” in which, for example, four device cycles are processed together. However, a mapping scheme may also be used in different modes, even in a mode in which individual bits of the received pattern are processed individually.

For example, the table-based definition 600 (which may be considered as a mapping description) comprises a plurality of lines 610a to 610n. For example, the table-based definition 600 may comprise a plurality of columns 612a to 612d, wherein the number of columns may vary between one column and a plurality of columns.

For example, one column is associated with each device cycle, but a different association is possible. For example, in a simple embodiment, there may be only one column, and this column may be associated with a single group of one or more bits.

Optionally, a line may have a repetition indicator 616 which may, for example, indicate whether a line should be repeated and/or which may indicate by how many times a line should be repeated. Optionally, a line may comprise a jump indicator (not shown) which may, for example, define to jump back to a previous line or to jump further to a following line.

In the examples shown in FIG. 6, the lines 610a, 610b, 610c, 610d (or at least some of the lines) comprise one data field per device cycle, wherein the data fields may, for example, comprise one functional block index (or core index) per bit associated with the respective device cycle. For example, if it is assumed that in the first four device cycles DC1, DC2, DC3, DC4 (described by the first line 610a) the bits of the received pattern should not be evaluated, an otherwise unused functional block index (e.g. “9”) is included in the data fields of the first line that are related to an association of bits of the received pattern to functional blocks. For example, the functional block indices for all bits of device cycle 1, of device cycle 2, of device cycle 3 and of device cycle 4 may be set to the otherwise unused functional block index value of 9. This may, for example, cause the control 340 or the mapping scheme 530 or the hardware mapper 540 to discard (not forward) error signals associated with the related device cycles.

For example, the first line 610a may also comprise a repetition indication 616, which indicates that the definitions of the first line 610 should be repeated n times. Accordingly, received bits of the received pattern of 4×n device cycles will be discarded. This may, for example be reasonable if it takes 4×n device cycles for a device under test to provide predictable (deterministic) results after the startup of a test. Accordingly, the received pattern associated with these 4×n device cycles will not contribute to an error registration, to an error counting or to an error recording (as used for a recording of individual signal information).

However, starting from line 1 (610b), one or more lines of the mapping 600 will define an association of bits of the received pattern to (actual) functional blocks (cores) of the device under test.

For example, a first entry of the line 610b may define that bits of the first device cycle are (all) associated with a first functional block of the device under test (functional block index “1”). A second entry in the line 610b may indicate that three bits of the second device cycle are associated with the second functional block of the device under test (functional block index “2”), and that the further bits of the second device cycle are associated with a third functional block (functional block index “3”). Moreover, a third entry of the line 610b may indicate that a first bit of the third device cycle may be associated with the third functional block of the device under test (functional block index “3”) and that the further bits of the third device cycle are associated with the fourth functional block of the device under test (functional block index “4”). Moreover, the fourth entry of the line 610b indicates that (all) the bits of the fourth device cycle are again associated with the first functional block of the device under test (functional block index “1”).

Moreover, the definitions in the lines 610c and 610d are similar. However, it is apparent from FIG. 6 that the bits associated with the different functional blocks of the device under test have a periodicity of, for example, three device cycles. Accordingly, in view of the fact that each of the lines 610b to 610d defines an association of bits of four device cycles to the functional blocks of the device under test, a periodicity, in terms of full lines of the table of FIG. 6, is reached at the end of the line 610d.

Accordingly, there may be an indication, e.g. in an entry of line 610d, or in an entry of a following line, or in a separate information, that the mapping should jump back to the beginning of line 610b when the mapping of line 610d has been completed. Accordingly, there will be a repetition of the association defined in lines 610b to 610d. Accordingly, a periodicity in the association of bit positions to functional blocks can be taken into account efficiently.

However, it should be noted that different mechanisms for defining the association of one or more blocks of bits with functional blocks of the device under test may be used. For example, in the case of large block lengths, it may be more efficient to define the length of the blocks of bits using a value (e.g. in terms of bits or in terms of bytes, or in terms of any length unit which seems to be appropriate), wherein it is still advantageous to use indications of repetitions or of jumps within such a table or listing.

To conclude, the concept described with respect to FIGS. 5 and 6 may optionally be used in any of the embodiments or in the present invention. However, it should be noted that the functionalities described with respect to FIGS. 5 and 6 may optionally be supplemented by any of the features, functionalities and details disclosed herein, both individually and taken in combination. Also, the concepts described with respect to FIGS. 5 and 6 may optionally be used alone.

In the following, it will be briefly described, as an example, how a result per core mapper (RPC, RPCM) can work. In an embodiment, the RPC looks at the compare results, but with a granularity of four device cycles. If the mapping description does not end at the end of a mapper line, it may be rolled out until it fits. For example, automated test equipment may operate in a X4 mode, wherein, for example, four device cycles are processed per step.

For example, if it is desired to initially ignore a number of test processor cycles, we can map to an unused core.

For example, a mapping begins in line #1.

At the end of line #3, we can program a jump back to the beginning of line #1—which will, in some cases, run for ever. For example, a reset will put the point back to the beginning of #0.

In other words, the table-based mechanism may be able to handle a jump instruction to jump to another line of the table, e.g., back to a previous line. An infinite repetition may be programmed which may, for example, be stopped by the test flow control 380 but alternatively, however, a number of repetitions may also be limited in the table-based mechanism.

However, it should be noted that these implementations should all be considered as being optional.

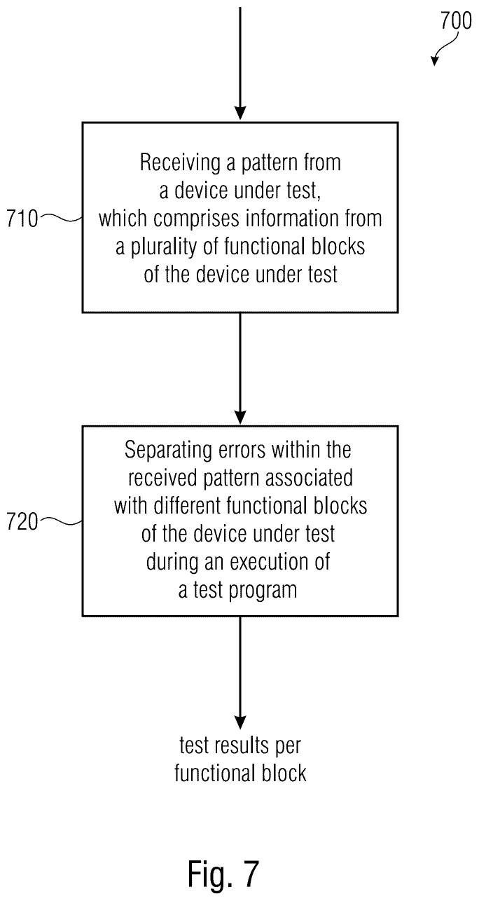

### 7. Method According to FIG. 7

FIG. 7 shows a flow chart of a method 700 for testing a device under test. The method 700, comprises receiving 710 a pattern from a device under test which comprises information from a plurality of functional blocks of the device under test. The method further comprises separating 720 errors within the received pattern associated with different functional blocks of the device under test during an execution of a test program. Accordingly, test results per functional block may be obtained using the method 700.

It should be noted that the method 700 is based on the same consideration as the above described test apparatuses.

Moreover, it should be noted that the method 700 may optionally be supplemented by any of the features, functionalities and details disclosed herein, both individually and taken in combination.

### 8. Further Aspects in Embodiments and Conclusions

In the following, the further aspects and details regarding the invention will be described. Moreover, according conclusions will be provided. However, it should be noted that any of the aspects and embodiments disclosed herein may optionally be combined with the other embodiments disclosed herein, both individually and taken in combination.

It should be noted that embodiments according to the invention create a result per core processor.

It should be noted that to increase the optimum usage of the available bandwidth for scan and functional testing, the players in EDA software and design for test started to work on methods to interleave the test patterns for a different cores when sending them through the test interface into the device under test (DUT), instead of sending the pure pattern (individual cores) to the target IP cores one by one. This will be done on the stimulus side for test, as well as on the device response side.

It has been recognized that it is advantageous to have special hardware to understand (e.g. evaluate) the device answer and to derive needed test flow decisions quickly.

In the following an overview over the underlying considerations will be provided.

To increase the optimum usage of the available bandwidth for scan and functional testing, the players in EDA software and design for test started to work on methods to interleave the test pattern for different cores when sending them through the test interface into the device under test (DUT), instead of sending the single core pattern (individual cores) to the target IP cores one by one.

It should be noted that, in the context of the present invention, a “core” denotes here a basic unit of the logic design, which shall be analysed in the testing separately (e.g. a unit of testing, e.g. the granularity of test results). Moreover, it should be noted that a “core” is an example of a “functional block”.

A level this is happening at may differ from case to case. For example, the invention covers the following examples, but is not limited to it:
As an example, the device under test may consist of four cores 1, 2, 3 and 4. The partitioning of the test data is like the below, the sequence repeats from 1 . . . . N times in a test pattern. N is typically in the range of 10,000 . . . , 50,0000 (but other values are also feasible)
   32 bits of core 1
   18 bits of core 2
   24 bits of core 3
   48 bits of core 4
As a second example, the sequence of cores is much longer, the cores might be interleaved or not to stop.
   10,000 bits for core 1
   32,000 bits of core 2
   50,320 bits of core 3
   200,010 bits of core 4
These sequence examples are expected to be different on all test pins involved in a test, as a special case they might be the same.

To conclude, the received pattern may, for example, comprise a plurality of groups of bits from different cores, wherein the received pattern may, for example, comprise a (e.g., periodic) repetition of sequences, wherein each sequence comprises, for example, a plurality of groups of one or more bits associated with different functional blocks (cores) of the device under test. However, it is not necessary to have a repetition of the sequence, e.g., if the sequence is relatively long.

FIG. 4 shows an example sequence of bits over time (columns, x axis) for different test pins (rows).

This will, for example, be done on the stimulus side for test, as well as on the device response side. On an automated test equipment (ATE) it is desirable to have a result processor which allows processing such patterns, which will be called “multi-core pattern” below.

In general, during a test execution, the stimulus pattern is sent to the device under test (DUT) (wherein, for example, the stimulus pattern is generated by the stimulus generator 390 shown in FIG. 3), and at the same time, the response of the device under test is compared against a response pattern (wherein the response pattern may, for example, be generated by the reference signal generator 326, and wherein the response pattern may be designated as a “reference pattern”, and wherein the response pattern may, for example, be represented by a reference signal 328). For example, both parts comprise a test pattern.

The comparison part (e.g., the comparator 320) checks the level information from the device under test (DUT) against an expected logical state, knowing the correct expected state (wherein the expected state may, for example, be defined by the reference pattern or by the reference signal). A response part of the pattern typically defines expect 0 (low, L), expect 1 (high, H) or mask (ignore the state, X).

If a deviation is recognized and the expected pattern does not state “X”, this is typically recorded in status flags (e.g., global and/or per signal) which highlight “comparison has failed” and a detailed error recording of numerous N failing cycles (an expected state in the sequence within a pattern) together with their addresses (sequence number).

While in the classical SCAN and functional test flow decision are often made based on the global pass/fail status flag and the per test signal pass/fail status flag, it has been recognized that this used model fails apart in the case of multicore patterns discussed above, because there is no identical mapping signal fail→core/function block fail any more, as many cores are behind a signal pin or could contribute to the failing test result. Therefore, it has been found that ATE architecture should bring in new elements to cope with these type of test patterns.

According to an aspect of the invention, the design of the result processor covers the following functionality (e.g. as . also defined in the claims).

Tracking of Test Results on a per Core Granularity

According to an aspect, there is a tracking of test results on a per core granularity.

According to an aspect of the invention, it is desired that the hardware supports multiple cores, wherein here a “core” refers to a result unit. Per this result unit is tracked whether fails have occurred in a test execution. As an example, the hardware could support 64 result units, which can be assigned to track the results of one or more IP cores in the device under test. This hardware is in the following called “core mapper”. It involves the mapping of fail positions to core in other blocks mentioned below (or generally mentioned herein).

For example, the error separator/error signal forwarder 332a may take part or all of the functionality of the so-called “core mapper”. However, the result units 336a, 336b, 336n may also take over part of the functionality of the so-called “core mapper”.

The core mapper may, for example, be able to track these test results per test execution, or per pattern used in this test execution (wherein, for example, intermediate results may be reset after a result pattern). Accordingly, for example, a temporal granularity of one test pattern may be achieved for the per-core-test results.

For the per pattern analysis, it might be desirable (or needed) to have fine granular control to reset (re-arm) the analyser as well as freeze and reset the result obtained in the just finished pattern and start from a clean state at the beginning of the next pattern.

For example, the reset inputs and/or the freeze inputs of the result units 336a, 336b, 336n may allow to reset the respective error flag registers and/or the respective error counters, wherein a time when to read out the result units 336a, 336b, 336n and/or when to reset the result units and/or when to “freeze” the result units may, for example, be determined by the control 340 or by the test flow control 380, depending on the requirements.

According to an aspect, it shall be also supported to start the core mapper only once per test execution and process all results at the end (e.g., after the test execution). For example, the test flow control 380 or the control 340 may control such a mechanism.

According to an aspect of the invention, the hardware should support short sequences of multiple cores as well as a sequence of long blocks, tested in a sequential order (see above).

### Results Per Core

According to an aspect, embodiments of the invention provide results per core.

According to an aspect, the hardware may be able to work in parallel to the usual compare fail recording performed in test equipment, and it may be able to record which of the cores have seen at least one compare fail. For example, the hardware may be configured to report the result discussed in here with a per single test pattern granularity or combined for a burst (list) of patterns. This e.g., can be implemented in a (sticky) bit in a core overview error map, which is set upon first fail and can then be read out after testing is completed.

For example, the error flag registers 337a, 337b, 337n may serve as “sticky bit” registers, and the outputs of these error flag registers may form, when taken together the “core overview error map”. Accordingly, by reading out the individual error flag registers or a “core overview error map” formed by a combination of the outputs of the error flag registers, it is possible to quickly obtain an overview which functional blocks of the device under test have generated at least one error in the received pattern.

For example, according to an aspect of the invention, this capability should be present also in case the failure recording (e.g., the failure recording performed by the error recorder 350) is limited or not executed at all, as the information on what core has seen a fail is important for test flow decisions (which may, for example, be made by the test flow control 380). Such decisions may, for example, involve additional test runs for further analysis of the failure (e.g., involving special diagnosis patterns) or branching into new test content for repair or similar.

For example, the overview error map should have the capability to be reset at the beginning of a pattern, or more general from the test execution controller (e.g., the test flow control 380) when appropriate. However, for example, individual resets of the error flag registers 337a, 337b, 337n may also be possible.

### Fail Log Requirements

In the following, some fail log requirements will be described, which can optionally be applied in some embodiments according to the invention.

In the first place, as the pattern for ATE test still originate from ATPG tools (e.g., from automatic test pattern generator tools), the data logger which generates STDF files (e.g., standard test data format files) shall record failing cycles as before and generate a STDF or otherwise formatted logger file for the EDA tools (electronic design automation tools) to analyse the device fails. In the first place, this is not to be changed.

In practical applications, the depth of the error map to record these errors is limited, to finding a balance between upload time and processing time. For the scenarios listed under description (or listed herein), this can lead to the effect that one heavily or fatally failing core, which generates a huge amount of compare files (or compare fails) in the response pattern, which prevents from analysing the cores or functions which are aimed in the sequence behind these heavy failing cores. In consequence, fail contributions of the elements tested later in one pattern may not be visible in the error recording.

The user however would know that the cores have failed from the sticky bits in the core overview error map.

In other words, the “core overview error map” or the outputs of the error flag registers 337a, 337b, 337n allow the user of the test apparatus (or the test flow control) to get a fast overview over the integrity of the functional blocks for the device under test.

### Per Core Masking Capability

In the following, a per core masking capability will be described, which may be implemented in embodiments according to the present invention.

According to an aspect of the invention, a central feature is the capability to mask compare fails. Traditionally, this is done by setting the expected state character for a bit to Mask (often designated with “X”). This is sometimes needed in classical test patterns to ignore initially failing states until a stable device state is reached, such that initial random internal states are discarded until the first test result of stimulus pattern is available. The same applies for regions in the test patterns where results are expected to be instable (e.g., logic and timing analysis patterns).

According to an aspect, this mythology is expanded to multi-core patterns, in the sense that results which can be attributed to a specific core can be masked on a per core basis. The applications include, but are not limited, to:
Masking the (wrong) results of fatally or heavily failing cores, as those would flood the error map recording and prevent the recording cores with just a few fails, if the length of the recording is for practical reasons (test time, post processing time) limited
Focused recording of one or more single cores.

For example, the per core masking capability may be achieved in a number of ways. For example, the test apparatus may automatically insert a mask information (e.g., a “X”) into the reference signal/reference pattern at the positions associated with a functional block to be masked (e.g. during the execution of a test program). Alternatively, the test apparatus may disable the comparator and/or the error recorder at the bit positions associated with a functional block to be masked. For example, the test apparatus may disable a forwarding of an error signalling from the comparator to the error recorder for a bit (or bit position) associated with a functional block of the device under test to be masked.

Thus, different hardware implementations may be used to obtain the automatic per core masking capability, wherein it should be noted that, in embodiments, the per core masking capability may be achieved “on the fly”, e.g., during the execution of a test program, without having the need to modify an input signal or input data of the reference signal generator/reference pattern generator (e.g. by introducing the masking behind (after) the output of the reference signal generator/reference pattern generator).

### Per Core Error Count Capability

In the following, a per core error count capability will be described. According to an aspect of the invention, new logic has been designed allowing the accurate counting of the fails we record per timing cycle not just in total but per core set up in the core table. For example, fails (e.g., comparison fails) may be recorded per core (e.g., per core set up in the core table).

This capability is useful (or even needed) to identify which cores (unit of testing) show fails good enough for analysis, and which cores do fail heavily. This capability is useful (or, in some cases needed) because it enables an analysis of which cores should be masked (or is to be masked) in a subsequent run of the same multi-core pattern when more results of specific cores for higher resolution result data is needed. For example, it enables decision which cores the test should focus on, core selection and hence can save the time needed for logging of results of heavily (fatally) failing cores the user is not interested in.

In other words, by counting failures, on a per functional block basis, it is possible to distinguish between functional blocks exhibiting no error, functional blocks exhibiting a small number of errors and functional blocks exhibiting a large number of errors. Accordingly, this information, indicating whether a functional block exhibits no error, or only a small number of errors or even a large number of errors, can be used to decide how to continue with the testing, wherein, for example, the test flow control 380 may use this information about the number of errors per functional block. For example, different test programs may be selected in dependence on the number of errors associated with different functional blocks, to thereby focus the testing on a heavily failing block if this is desired or to focus the testing on functional blocks exhibiting no errors or only a small number of errors in a preceding phase of the test. Consequently, efficiency can be improved.

### Per Core Auto-Masking Capability

In the following, a per core masking capability will be described, which can be used according to an aspect of the invention. This capability combines the accurate error counting with the masking capability. It also uses (or sometime involves) the addition of a comparison of the error count against a limit. If the limit is reached for one of the cores (or functional blocks) within a running test, the mask can, for example, be reprogrammed for the comparison of subsequent fails for this core to mask subsequent fails on this core. This enables the recording of a limited number of fails for every core, regardless of whether they occur in the very beginning or at the end of a test execution and avoid flooding or clogging.

For example, the control 340 may disable a recording of individual failure information associated with a certain heavily failing core by the error recorder 350 when an error counter associated with the certain core reaches or exceeds a threshold value. Consequently, an amount of individual failure information recorded per functional block of the device under test can be limited, which gives the possibility to record individual failure information for many different functional blocks or cores (or even for all functional blocks) even in the presence of one or more heavily failing functional blocks or cores. Consequently, efficient testing can be provided.

However, it should be noted that the per core masking capability, the per core error count capability and the per core auto-masking capability described herein should be considered as optional, such that it is not necessary to implement all of these functionalities within a specific embodiment of the invention.

### CONCLUSIONS

In the following, aspects of the invention will be briefly summarized.

The capabilities discussed here enable that, in some embodiments, most or all test results needed are available in a single execution of test patterns, e.g., without re-execution as the following results are available:
Pass/fail information per core, e.g., for flow decisions.
Absolute number of fails per every core→judge fatally failing and if a re-execution of a particular core is needed, for flow decisions
Limited number of fails recorded per core, e.g., for all cores→sufficient for data logging of the fails for post-processing in EDA Software
   First Failing Test Cycle, a standard information for analysis purposes can be obtained every core (e.g., guaranteed)
For the most cases, a re-execution is only needed when single cores should be re-executed for the purpose of the recording of huge amounts of compare fails
Disable certain cores for a test. In some cases, this involves the combination of two capabilities:
   Capability to disable the testing of individual cores in the design-for-test circuitry of the DUT (not in scope of this invention)
   The capability to mask the compare fails for the disabled cores, as in the comparison against the expected multi-core pattern will generate a multitude of (random) fails. (covered by aspects of this invention).

According to an aspect of this invention, this new hardware capability removes the need of complex post-processing and filtering of compare results by ATE software and dramatically reduces the amount of data to be recorded and post-processed. It also reduces the setup data size needed as specialized single core patterns can be removed and test time consumed by re-executions can be avoided.

Moreover, it should be noted that embodiments according to the invention can be used in digital cards, e.g., on digital channel modules for an automated test equipment.

In particular, embodiments according to the invention can be used in the V93000 automated test equipment, for example to improve T4 scan capabilities and to deal with multicore patterns.

### 9. Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A test apparatus for testing a device under test, comprising:
a signal receiver configured to receive a pattern from the device under test, which comprises information from a plurality of functional blocks of the device under test; and
an error separator configured to separate errors within the received pattern associated with different functional blocks of the plurality of functional blocks of the device under test during an execution of a test program.

2. The test apparatus according to claim 1,
wherein the error separator is configured to separate the errors within the received pattern associated with the different functional blocks of the device under test on-the-fly.

3. The test apparatus according to claim 1,
wherein the error separator is configured to separate the errors within the received pattern associated with the different functional blocks of the device under test in real time, and/or or in temporal synchronism with a data rate at which the received pattern is received from the device under test and/or in temporal synchronism with a data clock at which the received pattern is received from the device under test.

4. The test apparatus according to claim 1,
wherein the error separator is a dedicated hardware configured to separate the errors within the received pattern associated with the different functional blocks of the device under test.

5. The test apparatus according to claim 1, further comprising:
an error signal forwarding mechanism;
wherein the error signal forwarding mechanism comprises a dedicated hardware configured to selectively forward an error signal indicating a deviation of a bit value of a bit of the received pattern associated with a certain functional block of the device under test from an expected bit value defined by an expected pattern to a result unit associated with the certain functional block of the device under test.

6. The test apparatus according to claim 1, further comprising:
a disable mechanism;
wherein the disable mechanism comprises a dedicated hardware configured to selectively disable a comparison between one or more bits of the received pattern associated with a certain functional block of the device under test and one or more corresponding bits of an expected pattern, and/or
to selectively disable a forwarding of a result of a comparison between one or more bits of the received pattern associated with a certain functional block of the device under test and one or more corresponding bits of an expected pattern, and/or
to selectively disable a processing of a result of a comparison between one or more bits of the received pattern associated with a certain functional block of the device under test and one or more corresponding bits of an expected pattern.

7. The test apparatus according to claim 1, further comprising:
a bit block identification mechanism;
wherein the bit block identification mechanism comprises a dedicated hardware configured to identify different blocks of one or more bits of the received pattern associated with the different functional blocks of the device under test, in order to separate errors within the received pattern associated with the different functional blocks of the device under test.

8. The test apparatus according to claim 1, further comprising:
a bit block identification mechanism;
wherein the bit block identification mechanism comprises a dedicated hardware configured to identify different blocks of one or more bits of the received pattern using a table defining lengths of blocks of one or more bits of the received pattern associated with the different functional blocks of the device under test.

9. The test apparatus according to claim 1, further comprising:
a comparator, and
an error registration;
wherein the comparator is configured to compare the received pattern with an expected pattern; and
wherein the error registration is configured to separately register comparison failures associated with different blocks of one or more bits of the received pattern, and/or
to separately register comparison failures associated with the different functional blocks of the device under test.

10. The test apparatus according to claim 1, further comprising:
a plurality of individual result units configured to track test results associated with the different functional blocks of the device under test.

11. The test apparatus according to claim 1, further comprising:
a plurality of individual error flag registers associated with the different functional blocks of the device under test,
wherein the individual error flag registers are configured to be set in response to comparison errors between bits of the received pattern and corresponding bits of an expected pattern occurring in different blocks of one or more bits of the received pattern.

12. The test apparatus according to claim 1, further comprising:
a plurality of individual error counters;
wherein the individual error counters are associated with the different functional blocks of the device under test, and/or
wherein the individual error counters are configured to be incremented in response to comparison errors between bits of the received pattern and corresponding bits of an expected pattern occurring in different blocks of one or more bits of the received pattern.

13. The test apparatus according to claim 1, further comprising:
an error recorder and
an error registration;
wherein the error recorder is configured to record individual failure information indicating a respective failure position for a plurality of comparison failures, and
wherein the error registration is configured to acquire an overview failure information separately describing errors associated with the different functional blocks of the device under test in summary form,
wherein the error registration is configured to record a per-functional-block error flag and/or a per-functional-block error counting.

14. The test apparatus according to claim 13, further comprising:
a control mechanism,
wherein the control mechanism is configured to selectably mask a recording of individual failure information for bits of the received pattern which are associated with one or more of the functional blocks of the device under test; and/or
wherein the control mechanism is configured to selectably enable a recording of individual failure information for bits of the received pattern which are associated with one or more of the functional blocks of the device under test.

15. The test apparatus according to claim 14, further comprising:
a control mechanism;
wherein the control mechanism is configured to determine for which bits of the received pattern the recording of the individual failure information should be omitted using a table defining lengths of blocks of one or more bits of the received pattern associated with the different functional blocks of the device under test;
wherein the control mechanism comprises a dedicated hardware configured to identify bits of the received pattern for which the recording of the individual failure information should be omitted.

16. The test apparatus according to claim 14,
wherein the control mechanism is configured to activate a masking of the recording of individual failure information for bits of the received pattern which are associated with a certain functional block of the device under test in response to a detection that an individual error counter selectively counting comparison errors of bits associated with the certain functional block has reached a predetermined maximum value.

17. The test apparatus according to claim 1, further comprising:
a test flow control;
wherein the test flow control is configured to adapt a test flow in dependence on an information about an error within the received pattern associated with a given functional block of the device under test;
wherein the test flow control is configured to adapt the test flow in response to a determination that a number of errors in the received pattern which are associated with the given functional block of the device under test has reached or exceeded a predetermined maximum number.

18. The test apparatus according to claim 17, further comprising:
a control mechanism;
wherein the control mechanism is configured to activate a masking of a recording of individual failure information, or deactivate a recording of individual failure information, for bits of the received pattern which are associated with the given functional block of the device under test and to repeat a test in response to a determination that an number of errors in the received pattern which are associated with the given functional block of the device under test has reached or exceeded the predetermined maximum number.

19. A test apparatus for testing a device under test, comprising:
a signal receiver, and
an error separator;
wherein the signal receiver is configured to receive a pattern from the device under test, which comprises a sequence of bits;
wherein the error separator is configured to separate errors within the received pattern associated with different blocks of one or more bits during an execution of a test program.

20. A method for testing a device under test,
wherein the method comprises receiving a pattern from the device under test, which comprises information from a plurality of functional blocks of the device under test;
wherein the method comprises separating errors within the received pattern associated with different functional blocks of the device under test during an execution of a test program.
